(19) United States
(12) Patent Application Publication
(10) Pub. No.: US 2024/0266362 A1
(43) Pub. Date: Aug. 8, 2024

(54) DISPLAY DEVICE, METHOD OF FABRICATING THE DISPLAY DEVICE, AND TILED DISPLAY DEVICE INCLUDING A PLURALITY OF DISPLAY DEVICES

(71) Applicants: Samsung Display Co., LTD., Yongin-si (KR); NOKWON C&I Corporation, Paju-si (KR)

(72) Inventors: Nak Cho CHOI, Yongin-si (KR); Min Woo OH, Paju-si (KR); Jong Hwan BAE, Paju-si (KR); Sang Woo AN, Yongin-si (KR); Jae Chil HWANG, Yongin-si (KR); Myung Koo HUR, Yongin-si (KR)

(73) Assignees: Samsung Display Co., LTD., Yongin-si (KR); NOKWON C&I Corporation, Paju-si (KR)

(21) Appl. No.: 18/396,205

(22) Filed: Dec. 26, 2023

(30) Foreign Application Priority Data
Feb. 3, 2023 (KR) 10-2023-0014731

(51) Int. Cl. H01L 27/12; H01L 25/16

(52) U.S. Cl. CPC H01L 27/1244; H01L 25/167; H01L 27/1292; H01L 27/1218

(57) ABSTRACT

Provided are a display device, a method of fabricating the display device, and a tiled display device including display devices. A display device includes, a substrate including a first surface, a second surface opposite the first surface, and a first side surface disposed between the first surface and the second surface, a light emitting element disposed on the first surface, a side wiring disposed on the first surface, the first side surface, and the second surface, and an overcoat layer covering the side wiring, and the overcoat layer includes at least one of CaCO₃ and xCaO·ySiO₂·zH₂O where x, y, and z are natural numbers.

### CROSS-REFERENCE TO RELATED APPLICATION(S)

This application claims priority to and benefits of Korean Patent Application No. 10-2023-0014731 under 35 U.S.C. § 119, filed on Feb. 3, 2023, in the Korean Intellectual Property Office, the entire contents of which are incorporated herein by reference.

### BACKGROUND

### 1. Technical Field

The disclosure relates to a display device, a method of fabricating the display device, and a tiled display device including a plurality of display devices.

### 2. Description of the Related Art

As the information society develops, demands for display devices for displaying images are increasing in various forms. The display devices may be flat panel displays such as liquid crystal displays, field emission displays, and light emitting displays. The light emitting displays may include an organic light emitting display including an organic light emitting diode element as a light emitting element and a light emitting diode display including an inorganic light emitting diode element such as a light emitting diode (LED) as a light emitting element.

A display device may include a display area in which pixels displaying an image are disposed and a non-display area (or bezel area) which is disposed around the display area and in which wirings for driving the pixels are disposed. Recently, a bezel-less display device has been released to maximize the display area. Accordingly, there is an increasing demand for a display device in which wirings are formed on a side surface of a substrate to reduce the non-display area or completely eliminate the non-display area.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device including a protective layer with minimized expansion and peeling due to high temperature, high humidity, and external friction, a method of fabricating the display device, and a tiled display device including a plurality of display devices.

Aspects of the disclosure also provide a display device with minimized damage to side wirings, a method of fabricating the display device, and a tiled display device including a plurality of display devices.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, there is provided a display device that may include a substrate comprising a first surface; a second surface opposite the first surface; and a first side surface disposed between the first surface and the second surface; a light emitting element disposed on the first surface; a side wiring disposed on the first surface, the first side surface, and the second surface, and an overcoat layer covering the side wiring, wherein the overcoat layer comprises at least one of CaCO₃ and xCaO·ySiO₂·zH₂O where x, y, and z are natural numbers.

In an embodiment, xCaO·ySiO₂·zH₂O of the overcoat layer may be 3CaO·2SiO₂·3H₂O.

In an embodiment, the overcoat layer may comprise first particles comprising at least one of CaCO₃ and xCaO·ySiO₂·zH₂O and second particles comprising a light blocking pigment, wherein a size of the first particles is larger than a size of the second particles.

In an embodiment, the size of the first particles may be about 1 to about 3 times the size of the second particles.

In an embodiment, a surface of the overcoat layer may comprise substantially uneven patterns having irregular shapes, and a height difference between uppermost and lowermost ends of the substantially uneven patterns is within about 0.5 μm.

In an embodiment, xCaO·ySiO₂·zH₂O may be generated through a pozzolanic reaction by CaCO₃, SiO₂, and H₂O as reactants.

In an embodiment, an average thickness of the overcoat layer may be about 1 to about 3 times an average thickness of the side wiring.

In an embodiment, the overcoat layer may comprise at least one polymer selected from epoxy resin and acrylic resin.

In an embodiment, the substrate may comprise a first chamfered surface disposed between the first surface and the first side surface and a second chamfered surface disposed between the second surface and the first side surface, the side wiring may be further disposed on the first chamfered surface and the second chamfered surface, and the overcoat layer covers all of the first surface, the first chamfered surface, the first side surface, the second chamfered surface, and the second surface.

According to another aspect of the disclosure, there is provided a method of fabricating a display device, the method may include preparing a substrate comprising a first surface; a second surface opposite the first surface; and a first side surface disposed between the first surface and the second surface disposing light emitting elements on the first surface; forming a side wiring on the first surface, the first side surface, and the second surface; printing a paste on the substrate and the side wiring by a silicon pad; and forming an overcoat layer by curing the paste, wherein in the forming of the overcoat layer, CaCO₃ and SiO₂ included in the paste cause a pozzolanic reaction together with H₂O to generate xCaO·ySiO₂·zH₂O where x, y, and z are natural numbers.

In an embodiment, the paste may comprise a light blocking pigment, monomers, and a filler, and the filler is included at a range of about 10 to about 20 wt % based on the total mass of the paste.

In an embodiment, CaCO3 may be included at a range of about 12 to about 15 wt % based on the total mass of the paste, and SiO₂ is included at a range of about 2 to about 4 wt % based on the total mass of the paste.

In an embodiment, the monomers may comprise acrylic resin and/or epoxy resin.

In an embodiment, the forming of the paste may further comprise pulverizing particles of the filler through milling by zirconia balls.

In an embodiment, the overcoat layer may comprise first particles comprising at least one of CaCO₃ and xCaO·ySiO₂·zH₂O and second particles comprising a light blocking pigment, wherein a size of the first particles is larger than a size of the second particles.

In an embodiment, the size of the first particles may be about 1 to about 3 times the size of the second particles.

In an embodiment, the forming of the overcoat layer may comprise applying heat to the paste at a temperature in a range of about 180 to about 220° C. for about 25 to about 35 minutes.

In an embodiment, the forming of the overcoat layer may comprise thermally curing the paste by irradiating infrared light to the paste.

In an embodiment, the printing of the paste may further comprise applying the paste to an intaglio plate, and in the printing of the paste, the silicon pad is coated with the paste applied on the intaglio plate and prints the paste on the substrate and the side wiring.

According to another aspect of the disclosure, there is provided a tiled display device that may include, a first display device and a second display device; and a seam disposed between the first display device and the second display device and connects the first display device to the second display device, wherein each of the first display device and the second display device comprises, a substrate comprising a first surface; a second surface opposite the first surface; and a first side surface disposed between the first surface and the second surface; a light emitting element disposed on the first surface; a side wiring disposed on the first surface, the first side surface, and the second surface; and an overcoat layer covering the side wiring, wherein the overcoat layer comprises at least one of CaCO₃ and xCaO·ySiO₂·zH₂O where x, y, and z are natural numbers.

In a method of fabricating a display device and a tiled display device including a plurality of display devices according to embodiments, a protective layer with minimized expansion and peeling due to high temperature, high humidity, and external friction may be included.

In a method of fabricating a display device and a tiled display device including a plurality of display devices according to embodiments, damage to side wirings can be minimized.

However, the effects of the disclosure are not restricted to those set forth herein. The above and other effects of the disclosure will become more apparent to one of ordinary skill in the art to which the disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a top schematic perspective view of a display device according to an embodiment;

FIG. 2 is a bottom schematic perspective view of the display device according to the embodiment;

FIG. 3 illustrates an example of a pixel of FIG. 1;

FIG. 4 illustrates another example of the pixel of FIG. 1;

FIG. 5 is a detailed enlarged view of an edge of the display device according to an embodiment;

FIG. 6 is a schematic plan view of the edge of the display device according to an embodiment;

FIG. 7 is a rear view of the edge of the display device according to an embodiment;

FIG. 8 is a schematic cross-sectional view of an example of a display panel taken along line A-A′ of FIG. 3;

FIG. 9 is a schematic cross-sectional view of an example of the display panel taken along line B-B′ of FIG. 7;

FIG. 10 is a schematic plan view illustrating a substrate, side wirings, and an overcoat layer according to an embodiment;

FIG. 11 is an enlarged view of portion ‘A’ in FIG. 10;

FIGS. 12A and 12B each are a photograph comparing a surface of a conventional overcoat layer and a surface of an overcoat layer according to an embodiment;

FIG. 13 is a flowchart illustrating a method of fabricating a display device according to an embodiment;

FIGS. 14 through 16B are example views for explaining operation S200 of FIG. 13;

FIGS. 17 and 18 are example views for explaining operation S300 of FIG. 13;

FIGS. 19 and 20 are example views for explaining operation S400 of FIG. 13;

FIG. 21 is a schematic plan view of a tiled display device according to an embodiment;

FIG. 22 is an enlarged schematic plan view illustrating area E of FIG. 21 in detail;

FIG. 23 is a schematic cross-sectional view of an example of the tiled display device taken along line E-E′ of FIG. 22; and

FIG. 24 is a block diagram of the tiled display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

In this specification, it will be understood that when an element (or a region, a layer, a portion, or the like) is referred to as “being on”, “connected to” or “coupled to” another element, it may be directly disposed on/connected/coupled to the other element, or intervening elements may be disposed therebetween.

It will be understood that the terms “connected to” or “coupled to” may include a physical or electrical connection or coupling.

Like reference numerals or symbols refer to like elements throughout. In the drawings, the thickness, the ratio, and the dimension of the elements are exaggerated for effective description of the technical contents.

In the specification and the claims, the term “and/of” is intended to include any combination of the terms “and” and “or” for the purpose of its meaning and interpretation. For example, “A and/or B” may be understood to mean “A, B, or A and B.” The terms “and” and “of” may be used in the conjunctive or disjunctive sense and may be understood to be equivalent to “and/or.”

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The singular forms include the plural forms as well, unless the context clearly indicates otherwise. For example, as used herein, the singular forms, “a,” “an,” and “the” are intended to include the plural forms as well, unless the context clearly indicates otherwise.

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms such as “below”, “lower”, “above”, “upper” and the like, may be used herein for the description to describe one element's relationship to another element illustrated in the figures. It will be understood that the terms have a relative concept and are described on the basis of the orientation depicted in the figures.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

It will be understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Features of various embodiments may be combined partially or totally. As will be clearly appreciated by those skilled in the art, technically various interactions and operations are possible. Various embodiments can be practiced individually or in combination.

Hereinafter, disclosed embodiments will be described with reference to the accompanying drawings.

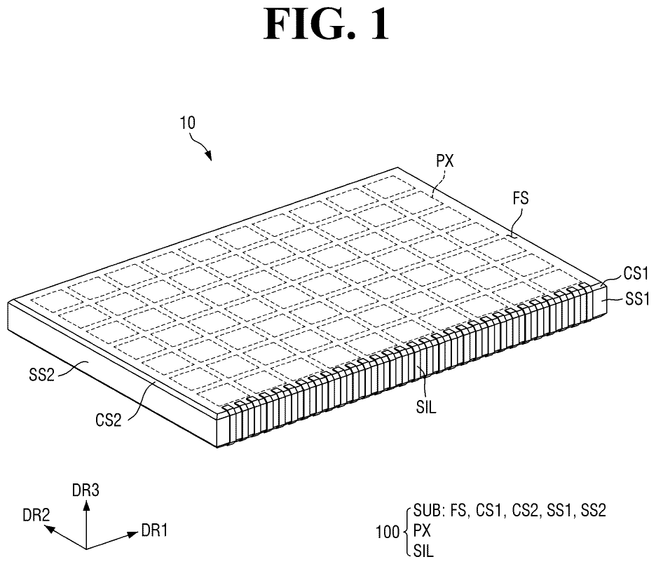

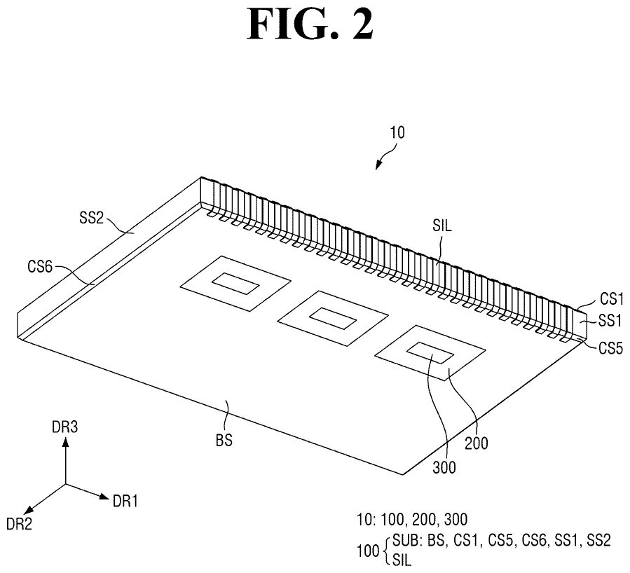

FIG. 1 is a top schematic perspective view of a display device 10 according to an embodiment. FIG. 2 is a bottom perspective view of the display device 10 according to the embodiment.

Referring to FIGS. 1 and 2, the display device 10 according to the embodiment is a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards and Internet of things (loT) devices.

The display device 10 according to the embodiment may include a display panel 100, circuit boards 200, and display driving circuits 300.

The display panel 100 may include a substrate SUB, a plurality of pixels PX, and a plurality of side wirings SIL. The substrate SUB may include a first surface FS, a second surface BS, a plurality of chamfered surfaces CS1 through CS8, and a plurality of side surfaces SS1 through SS4.

The first surface FS may be a front surface of the substrate SUB. The first surface FS may have a rectangular shape having long sides in a first direction DR1 and short sides in a second direction DR2.

The second surface BS may be a surface opposite the first surface FS. The second surface BS may be a rear surface of the substrate SUB. The second surface BS may have a rectangular shape having long sides in the first direction DR1 and short sides in the second direction DR2. The second surface BS may be a surface opposite the first surface FS.

In the drawings, the first direction DR1 and the second direction DR2 are horizontal directions intersecting each other. For example, the first direction DR1 and the second direction DR2 may be orthogonal to each other. A third direction DR3 may be a vertical direction intersecting, for example, orthogonal to the first direction DR1 and the second direction DR2.

The chamfered surfaces CS1 through CS8 refer to obliquely cut surfaces disposed between the first surface FS and the side surfaces SS1 through SS4 and between the second surface BS and the side surfaces SS1 through SS4 to prevent chipping defects of the side wirings SIL. Due to the chamfered surfaces CS1 through CS8, a bending angle of each of the side wirings SIL may be gentle. Thus, chipping or cracking of the side wirings SIL can be prevented.

A first chamfered surface CS1 may extend from a first side, for example, a lower side of the first surface FS. A second chamfered surface CS2 may extend from a second side, for example, a left side of the first surface FS. Although not illustrated in the drawings, a third chamfered surface CS3 may extend from a third side, for example, an upper side of the first surface FS. Although not illustrated in the drawings, a fourth chamfered surface CS4 may extend from a fourth side, for example, a right side of the first surface FS. An internal angle formed by the first surface FS and the first chamfered surface CS1, an internal angle formed by the first surface FS and the second chamfered surface CS2, an internal angle formed by the first surface FS and the third chamfered surface CS3, and an internal angle formed by the first surface FS and the fourth chamfered surface CS4 may be greater than 90 degrees.

A fifth chamfered surface CS5 may extend from a first side, for example, a lower side of the second surface BS. A sixth chamfered surface CS6 may extend from a second side, for example, a left side of the second surface BS. Although not illustrated in the drawings, a seventh chamfered surface CS7 may extend from a third side, for example, an upper side of the second surface BS. Although not illustrated in the drawings, an eighth chamfered surface CS8 may extend from a fourth side, for example, a right side of the second surface BS. An internal angle formed by the second surface BS and the fifth chamfered surface CS5, an internal angle formed by the second surface BS and the sixth chamfered surface CS6, an internal angle formed by the second surface BS and the seventh chamfered surface CS7, and an internal angle formed by the second surface BS and the eighth chamfered surface CS8 may be greater than 90 degrees.

A first side surface SS1 may extend from the first chamfered surface CS1. The first chamfered surface CS1 may be disposed between the first surface FS and the first side surface SS1. The first side surface SS1 may be a lower side surface of the substrate SUB.

A second side surface SS2 may extend from the second chamfered surface CS2. The second chamfered surface CS2 may be disposed between the first surface FS and the second side surface SS2. The second side surface SS2 may be a left side surface of the substrate SUB.

A third side surface SS3 may extend from the third chamfered surface CS3. The third chamfered surface CS3 may be disposed between the first surface FS and the third side surface SS3. The third side surface SS3 may be an upper side surface of the substrate SUB.

A fourth side surface SS4 may extend from the fourth chamfered surface CS4. The fourth chamfered surface CS4 may be disposed between the first surface FS and the fourth side surface SS4. The fourth side surface SS4 may be a right side surface of the substrate SUB.

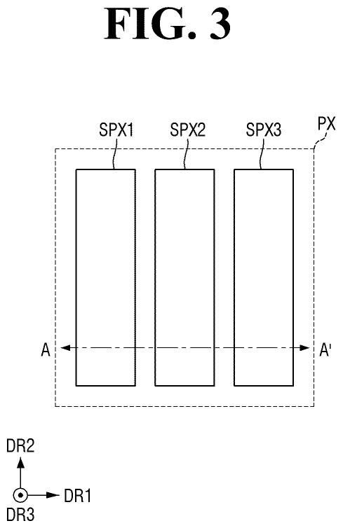

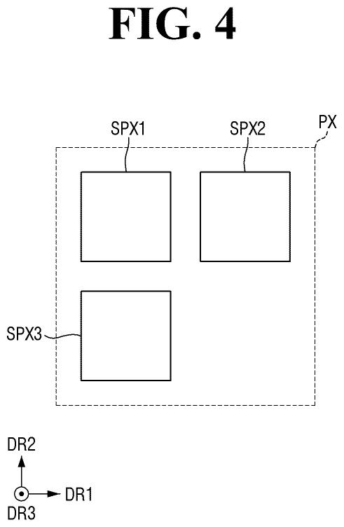

The pixels PX may be disposed on the first surface FS of the substrate SUB to display an image. The pixels PX may be arranged (or disposed) in a matrix form in the first direction DR1 and the second direction DR2. The pixels PX will be described in detail later with reference to FIGS. 3 and 4.

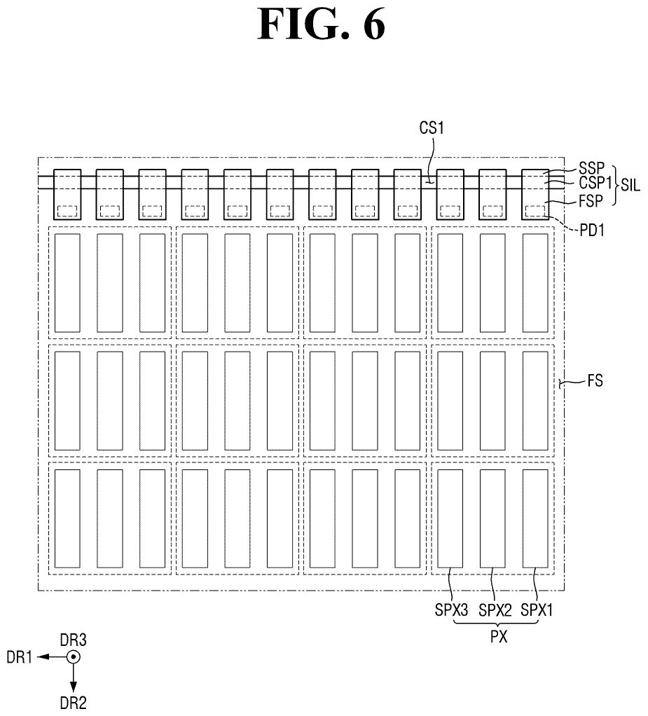

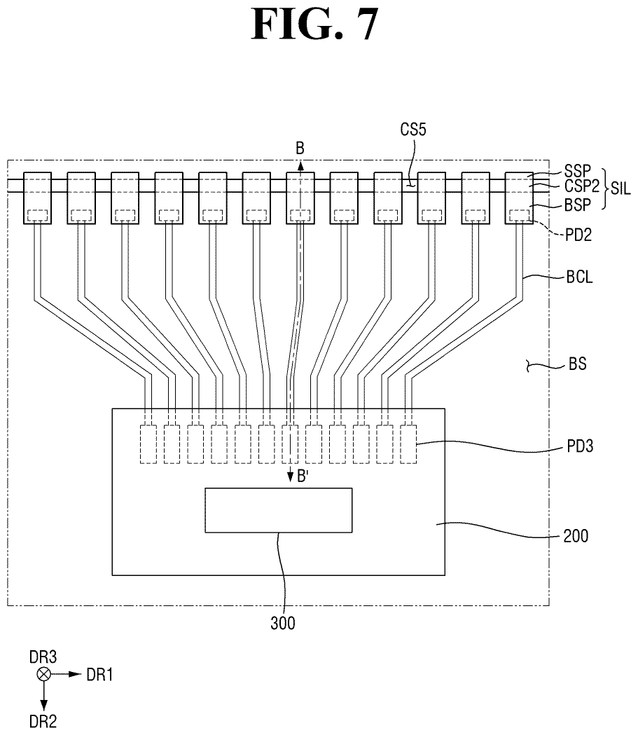

Each of the side wirings SIL connects a first pad PD1 (see FIG. 6), for example, a front pad disposed on the first surface FS and a second pad PD2 (see FIG. 7), for example, a rear pad disposed on the second surface BS. The first pads PD1 (see FIG. 6) may be connected to data wirings connected to the pixels PX of the substrate SUB.

The side wirings SIL may be disposed on the first surface FS, the second surface BS, at least any two of the chamfered surfaces CS1 through CS8, and at least any one of the side surfaces SS1 through SS4. For example, the side wirings SIL may be disposed on the first surface FS, the second surface BS, the first chamfered surface CS1, the fifth chamfered surface CS5, and the first side surface SS1 to connect the first pads PD1 (see FIG. 6) disposed on the first side of the first surface FS and the second pads PD2 (see FIG. 7) disposed on the first side of the second surface BS.

In case that the display panel 100 additionally may include the first pads PD1 (see FIG. 6) disposed on the second side of the first surface FS of the substrate SUB and the second pads PD2 (see FIG. 7) disposed on the second side of the second surface BS of the substrate SUB, the side wirings SIL may be additionally disposed on the first surface FS, the second surface BS, the second chamfered surface CS2, the sixth chamfered surface CS6, and the second side surface SS2. In case that the display panel 100 additionally may include the first pads PD1 (see FIG. 6) disposed on the third side of the first surface FS of the substrate SUB and the second pads PD2 (see FIG. 7) disposed on the third side of the second surface BS, the side wirings SIL may be additionally disposed on the first surface FS, the second surface BS, the third chamfered surface CS3, the seventh chamfered surface CS7, and the third side surface SS3. Furthermore, in case that the display panel 100 additionally may include the first pads PD1 (see FIG. 6) disposed on the fourth side of the first surface FS of the substrate SUB and the second pads PD2 (see FIG. 7) disposed on the fourth side of the second surface BS, the side wirings SIL may be additionally disposed on the first surface FS, the second surface BS, the fourth chamfered surface CS4, the eighth chamfered surface CS8, and the fourth side surface SS4.

The circuit boards 200 may be disposed on the second surface BS of the substrate SUB. Each of the circuit boards 200 may be connected to third pads PD3 (see FIG. 7) disposed on the second surface BS of the substrate SUB by using a conductive adhesive member such as an anisotropic conductive film. As will be described later with reference to FIG. 7, the third pads PD3 (see FIG. 7) are electrically connected to the second pads PD2, respectively. Accordingly, the circuit boards 200 may be electrically connected to the first pads PD1 through the side wirings SIL. Each of the circuit boards 200 may be a flexible printed circuit board, a printed circuit board, or a flexible film such as a chip on film.

The display driving circuits 300 may generate data voltages and supply the data voltages to the data wirings through the circuit boards 200, the third pads PD3 (see FIG. 7), the second pads PD2 (see FIG. 7), the side wirings SIL, and the first pads PD1 (see FIG. 6). The display driving circuits 300 may be formed as integrated circuits and attached onto the circuit boards 200. For example, the display driving circuits 300 may be directly attached to the second surface BS of the substrate SUB by using a chip on glass (COG) method.

As illustrated in FIG. 1, since the first pads PD1 (see FIG. 6) disposed on the first surface FS and the second pads PD2 (see FIG. 7) disposed on the second surface BS are connected using the side wirings SIL, a flexible film bent along a side surface of the substrate SUB can be eliminated. Accordingly, a bezel-less display device can be implemented.

FIG. 3 illustrates an example of a pixel PX of FIG. 1. FIG. 4 illustrates another example of the pixel PX of FIG. 1.

Referring to FIGS. 3 and 4, each of the pixels PX may include a plurality of subpixels SPX1 through SPX3. In FIGS. 3 and 4, each of the pixels PX may include three subpixels SPX1 through SPX3, for example, a first subpixel SPX1, a second subpixel SPX2, and a third subpixel SPX3, but embodiments are not limited thereto. Each of the first subpixel SPX1, the second subpixel SPX2, and the third subpixel SPX3 may be connected to any one of the data wirings and at least one of scan wirings.

Each of the first subpixel SPX1, the second subpixel SPX2, and the third subpixel SPX3 may have a rectangular, square, or rhombic planar shape. For example, each of the first subpixel SPX1, the second subpixel SPX2, and the third subpixel SPX3 may have a rectangular planar shape having short sides in the first direction DR1 and long sides in the second direction DR2 as illustrated in FIG. 3. For example, each of the first subpixel SPX1, the second subpixel SPX2, and the third subpixel SPX3 may have a square or rhombic planar shape including sides having the same length in the first direction DR1 and the second direction DR2 as illustrated in FIG. 4.

In an embodiment, the first subpixel SPX1, the second subpixel SPX2, and the third subpixel SPX3 may be arranged in the first direction DR1. For example, as illustrated in illustrated in FIG. 3, the first subpixel SPX1, the second subpixel SPX2, and the third subpixel SPX3 may be sequentially arranged along the first direction DR1. For another example, the first subpixel SPX1, the second subpixel SPX2, and the third subpixel SPX3 may be arranged in the order of the first subpixel SPX1, the third subpixel SPX3 and the second subpixel SPX2, in the order of the second subpixel SPX2, the first subpixel SPX1 and the third subpixel SPX3, in the order of the second subpixel SPX2, the third subpixel SPX3 and the first subpixel SPX1, in the order of the third subpixel SPX3, the first subpixel SPX1 and the second subpixel SPX2, or in the order of the third subpixel SPX3, the second subpixel SPX2 and the first subpixel SPX1.

In an embodiment, any one of the second subpixel SPX2 and the third subpixel SPX3 and the first subpixel SPX1 may be arranged in the first direction DR1, and the other one of the second subpixel SPX2 and the third subpixel SPX3 and the first subpixel SPX1 may be arranged in the second direction DR2. For example, as illustrated in FIG. 4, the first subpixel SPX1 and the second subpixel SPX2 may be arranged in the first direction DR1, and the first subpixel SPX1 and the third subpixel SPX3 may be arranged in the second direction DR2.

In an embodiment, any one of the first subpixel SPX1 and the third subpixel SPX3 and the second subpixel SPX2 may be arranged in the first direction DR1, and the other one of the first subpixel SPX1 and the third subpixel SPX3 and the second subpixel SPX2 may be arranged in the second direction DR2. For example, any one of the first subpixel SPX1 and the second subpixel SPX2 and the third subpixel SPX3 may be arranged in the first direction DR1, and the other one of the first subpixel SPX1 and the second subpixel SPX2 and the third subpixel SPX3 may be arranged in the second direction DR2.

The first subpixel SPX1 may emit first light, the second subpixel SPX2 may emit second light, and the third subpixel SPX3 may emit third light. Here, the first light may be light of a red wavelength band, the second light may be light of a green wavelength band, and the third light may be light of a blue wavelength band. The red wavelength band may be a wavelength band of about 600 to 750 nm, the green wavelength band may be a wavelength band of about 480 to 560 nm, and the blue wavelength band may be a wavelength band of about 370 to 460 nm. However, embodiments are not limited thereto.

Each of the first subpixel SPX1, the second subpixel SPX2, and the third subpixel SPX3 may include an inorganic light emitting element having an inorganic semiconductor as a light emitting element that emits light. For example, the inorganic light emitting element may be a flip-chip type micro-light emitting diode (LED), but embodiments are not limited thereto.

As illustrated in FIGS. 3 and 4, the area of the first subpixel SPX1, the area of the second subpixel SPX2, and the area of the third subpixel SPX3 may be substantially the same. However, embodiments are not limited thereto. At least any one of the area of the first subpixel SPX1, the area of the second subpixel SPX2, and the area of the third subpixel SPX3 may be different from another one. For example, any two of the area of the first subpixel SPX1, the area of the second subpixel SPX2, and the area of the third subpixel SPX3 may be substantially the same, and the other one may be different from the two. For example, the area of the first subpixel SPX1, the area of the second subpixel SPX2, and the area of the third subpixel SPX3 may be different from each other.

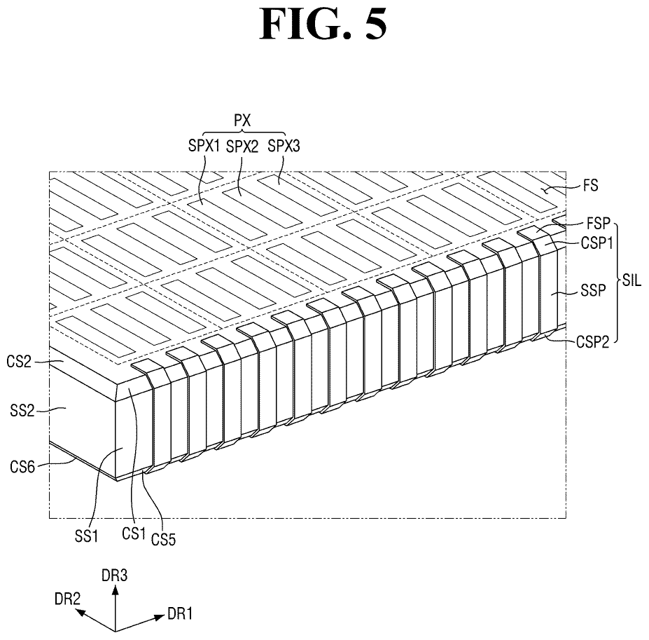

FIG. 5 is a detailed enlarged view of an edge of the display device 10 according to the embodiment. FIG. 6 is a schematic plan view of the edge of the display device 10 according to an embodiment. FIG. 7 is a rear view of the edge of the display device 10 according to an embodiment.

Referring to FIGS. 5 through 7, the display panel 100 may include the first pads PD1, the second pads PD2, the third pads PD3, and rear connection wirings BCL.

The first pads PD1 may be front pads disposed on the first surface FS corresponding to the front surface of the substrate SUB. The first pads PD1 may be disposed at an edge on the first side of the first surface FS of the substrate SUB. The first pads PD1 may be arranged in the first direction DR1.

The second pads PD2 may be rear pads disposed on the second surface BS corresponding to the rear surface of the substrate SUB. The second pads PD2 may be disposed at an edge on the first side of the second surface BS of the substrate SUB. The second pads PD2 may be arranged in the first direction DR1.

The third pads PD3 may be rear pads disposed on the second surface BS of the substrate SUB. The third pads PD3 may be disposed closer to the center of the second surface BS of the substrate SUB than the second pads PD2. The third pads PD3 may be arranged in the first direction DR1. A distance between the third pads PD3 neighboring each other in the first direction DR1 may be smaller than a distance between the second pads PD2 neighboring each other in the first direction DR1 so that more third pads PD3 can be connected to a circuit board 200.

The rear connection wirings BCL connect the second pads PD2 and the third pads PD3. Since the distance between the second pads PD2 neighboring each other in the first direction DR1 and the distance between the third pads PD3 neighboring each other in the first direction DR1 are different, the rear connection wirings BCL may be bent at least once. The rear connection wirings BCL may be integral with the second pads PD2 and the third pads PD3. Each of the second pads PD2, the third pads PD3, and the rear connection wirings BCL may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

Each of the side wirings SIL may include first through fifth portions FSP, CSP1, SSP, CSP2, and BSP.

The first portion FSP corresponds to a front portion disposed on the first surface FS of the substrate SUB. The first portion FSP may be disposed on a first pad PD1 and may completely cover the first pad PD1. The first portion FSP may be connected to the first pad PD1.

The second portion CSP1 corresponds to a first chamfered portion disposed on the first chamfered surface CS1 of the substrate SUB. The second portion CSP1 may be disposed between the first portion FSP and the third portion SSP.

The third portion SSP corresponds to a side portion disposed on the first side surface SS1 of the substrate SUB. The third portion SSP may be disposed between the second portion CSP1 and the fourth portion CSP2.

The fourth portion CSP2 corresponds to a second chamfered portion disposed on the fifth chamfered surface CS5 of the substrate SUB. The fourth portion CSP2 may be disposed between the third portion SSP and the fifth portion BSP.

The fifth portion BSP corresponds to a rear portion disposed on the second surface BS of the substrate SUB. The fifth portion BSP may be disposed on a second pad PD2 and may completely cover the second pad PD2. The fifth portion BSP may be connected to the second pad PD2.

The side wirings SIL may include metal powder including metal particles such as silver (Ag) and copper (Cu) and a polymer such as acrylic resin or epoxy resin. The metal powder may allow the side wirings SIL to have conductivity, and the polymer may serve as a binder connecting the metal particles.

By way of example, the side wirings SIL may be formed by printing a metal paste including metal particles, monomers and a solvent on the substrate SUB using a silicon pad and then sintering the metal paste using laser light. As the monomers react to transform into a polymer due to the heat of the laser light during the sintering process, the metal particles may be closely attached and agglomerated with each other. Accordingly, the resistivity of the side wirings SIL may be lowered.

In an embodiment, a thickness of the second portion CSP1 and a thickness of the fourth portion CSP2 may be smaller than a thickness of the first portion FSP, a thickness of the third portion SSP, and a thickness of the fifth portion BSP. For example, the thickness of the second portion CSP1 and the thickness of the fourth portion CSP2 may be in a range of about 1 to about 3 μm, and the thickness of the first portion FSP, the thickness of the third portion SSP and the thickness of the fifth portion BSP may be in a range of about 3 to about 5 μm. This may be because in the process of applying the metal paste using the silicon pad during the formation of the side wirings SIL, the force applied by the silicon pad on the first chamfered surface CS1 and the fifth chamfered surface CS5 is greater than the force applied by the silicon pad on the first surface FS, the second surface BS, and the first side surface SS1. The second portion CSP1 and the fourth portion CSP2 of each side wiring SIL are highly likely to be damaged by laser light during the sintering process. Therefore, the sintering process using laser light may not be performed on the second portion CSP1 and the fourth portion CSP2.

In an embodiment, the metal packing density of the first portion FSP and the fifth portion BSP may be higher than the metal packing density of the third portion SSP, and the metal packing density of the third portion SSP may be higher than the metal packing density of the second portion CSP1 and the fourth portion CSP2. The metal packing density refers to the proportion of metal particles in a given space. Accordingly, the resistivity of the first portion FSP and the resistivity of the fifth portion BSP of each side wiring SIL may be lower than the resistivity of the third portion SSP of each side wiring SIL. The resistivity of the third portion SSP of each side wiring SIL may be lower than the resistivity of the second portion CSP1 and the resistivity of the fourth portion CSP2 of each side wiring SIL.

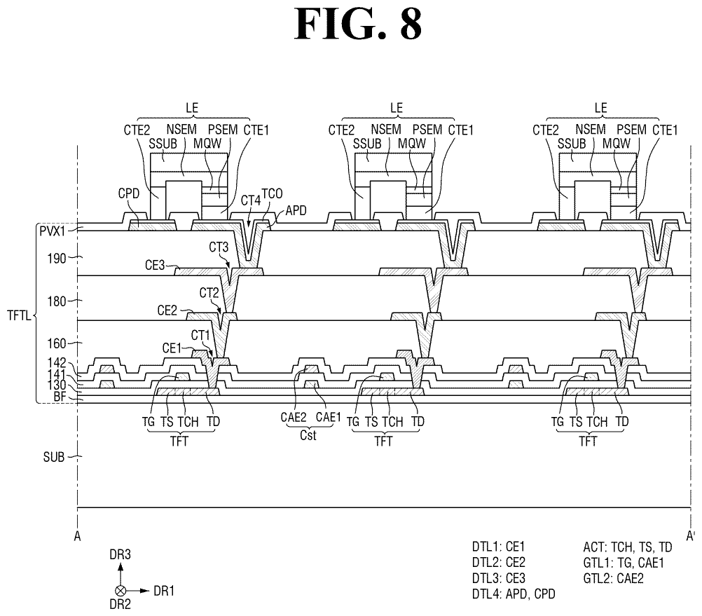

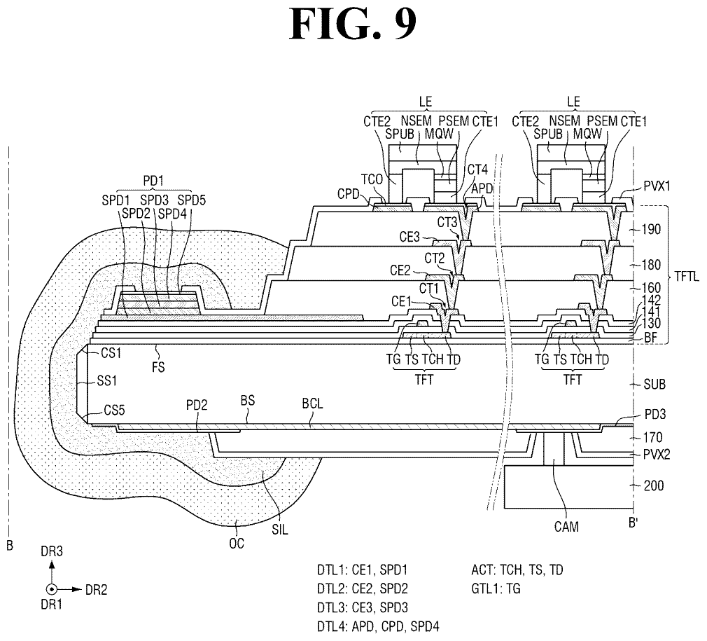

FIG. 8 is a schematic cross-sectional view of an example of the display panel 100 taken along line A-A′ of FIG. 3. FIG. 9 is a schematic cross-sectional view of an example of the display panel 100 taken along line B-B′ of FIG. 7.

Referring to FIGS. 8 and 9, the display panel 100 may include a thin-film transistor layer TFTL and light emitting elements LE disposed on the substrate SUB. The thin-film transistor layer TFTL may be a layer in which thin-film transistors TFT are formed.

The thin-film transistor layer TFTL may include an active layer ACT, a first gate layer GTL1, a second gate layer GTL2, a first data metal layer DTL1, a second data metal layer DTL2, a third data metal layer DTL3, and a fourth data metal layer DTL4. The thin-film transistor layer TFTL may include a buffer layer BF, a gate insulating layer 130, a first interlayer insulating film 141, a second interlayer insulating film 142, a first planarization layer 160, a second planarization layer 180, and a third planarization layer 190.

The substrate SUB may be a base substrate or a base member for supporting the display device 10. The substrate SUB may be a rigid substrate made of glass, but embodiments are not limited thereto. The substrate SUB may also be a flexible substrate that can be bent, folded, rolled, or the like within the spirit and the scope of the disclosure. The substrate SUB may include an insulating material, for example, polymer resin such as polyimide (PI).

The buffer layer BF may be disposed on a surface of the substrate SUB. The buffer layer BF may be a layer for preventing penetration of air or moisture. The buffer layer BF may be composed of a plurality of inorganic layers alternately stacked each other. For example, the buffer layer BF may be a multilayer in which one or more inorganic layers selected from a silicon nitride layer, a silicon oxynitride layer, a silicon oxide layer, a titanium oxide layer, and an aluminum oxide layer may be alternately stacked each other. The buffer layer BF may also be omitted.

The active layer ACT may be disposed on the buffer layer BF. The active layer ACT may include a silicon semiconductor such as polycrystalline silicon, monocrystalline silicon, low-temperature polycrystalline silicon or amorphous silicon or may include an oxide semiconductor.

The active layer ACT may include a channel TCH, a first electrode TS, and a second electrode TD of each thin-film transistor TFT. The channel TCH of each thin-film transistor TFT may be a region overlapping a gate electrode TG of the thin-film transistor TFT in the third direction DR3 which is a thickness direction of the substrate SUB. The first electrode TS of each thin-film transistor TFT may be disposed on one side or a side of the channel TCH, and the second electrode TD may be disposed on the other side of the channel TCH. The first electrode TS and the second electrode TD of each thin-film transistor TFT may be regions not overlapping the gate electrode TG in the third direction DR3. The first electrode TS and the second electrode TD of each thin-film transistor TFT may be regions formed to have conductivity by doping a silicon semiconductor or an oxide semiconductor with ions.

The gate insulating layer 130 may be disposed on the active layer ACT. The gate insulating layer 130 may be made of an inorganic layer, for example, a silicon nitride layer, a silicon oxynitride layer, a silicon oxide layer, a titanium oxide layer, or an aluminum oxide layer.

The first gate layer GTL1 may be disposed on the gate insulating layer 130. The first gate layer GTL1 may include the gate electrode TG of each thin-film transistor TFT and first capacitor electrodes CAE1. The first gate layer GTL1 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The first interlayer insulating film 141 may be disposed on the first gate layer GTL1. The first interlayer insulating film 141 may be made of an inorganic layer, for example, a silicon nitride layer, a silicon oxynitride layer, a silicon oxide layer, a titanium oxide layer, or an aluminum oxide layer.

The second gate layer GTL2 may be disposed on the first interlayer insulating film 141. The second gate layer GTL2 may include second capacitor electrodes CAE2. The second gate layer GTL2 may be a single layer or a multilayer made of any one or more of molybdenum (Mo), aluminum (Al), chromium (Cr), gold (Au), titanium (Ti), nickel (Ni), neodyniun (Nd), copper (Cu), and alloys thereof.

The second interlayer insulating film 142 may be disposed on the second gate layer GTL2. The second interlayer insulating film 142 may be made of an inorganic layer, for example, a silicon nitride layer, a silicon oxynitride layer, a silicon oxide layer, a titanium oxide layer, or an aluminum oxide layer.

The first data metal layer DTL1 may be disposed on the second interlayer insulating film 142. The first data metal layer DTL1 may be a single layer or a multilayer made of any one or more of molybdenum (Mo), aluminum (Al), chromium (Cr), gold (Au), titanium (Ti), nickel (Ni) neodymium (Nd), copper (Cu), and alloys thereof.

The first data metal layer DTL1 may include first connection electrodes CE1, a first sub-pad SPD1, and a data wiring DL. The data wiring DL may be integral with the first sub-pad SPD1, but embodiments are not limited thereto. Each of the first connection electrodes CE1 may be connected to the first electrode TS or the second electrode TD of a thin-film transistor TFT through a first contact hole CT1 penetrating the gate insulating layer 130, the first interlayer insulating film 141 and the second interlayer insulating film 142. The first sub-pad SPD1 may be formed of the same material or a similar material as the first connection electrodes CE1 in the same process, but embodiments are not limited thereto.

The first planarization layer 160 may be disposed on the first data metal layer DTL1. The first planarization layer 160 may flatten steps due to the active layer ACT, the first gate layer GTL1, the second gate layer GTL2, and the first data metal layer DTL1. The first planarization layer 160 may be made of an organic layer such as acryl resin, epoxy resin, phenolic resin, polyamide resin, or polyimide resin.

The second data metal layer DTL2 may be disposed on the first planarization layer 160. The second data metal layer DTL2 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second data metal layer DTL2 may include second connection electrodes CE2 and a second sub-pad SPD2. Each of the second connection electrodes CE2 may be connected to a first connection electrode CE1 through a second contact hole CT2 penetrating the first planarization layer 160. The second sub-pad SPD2 may be formed of the same material or a similar material as the second connection electrodes CE2 in the same process, but embodiments are not limited thereto.

The second planarization layer 180 may be disposed on the second data metal layer DTL2. The second planarization layer 180 may flatten steps due to the second data metal layer DTL2. The second planarization layer 180 may be made of an organic layer such as acryl resin, epoxy resin, phenolic resin, polyamide resin, or polyimide resin.

The third data metal layer DTL3 may be disposed on the second planarization layer 180. The third data metal layer DTL3 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The third data metal layer DTL3 may include third connection electrodes CE3 and a third sub-pad SPD3. Each of the third connection electrodes CE3 may be connected to a second connection electrode CE2 through a third contact hole CT3 penetrating the second planarization layer 180. The third sub-pad SPD3 may be formed of the same material or a similar material as the third connection electrodes CE3 in the same process, but embodiments are not limited thereto.

The third planarization layer 190 may be disposed on the third data metal layer DTL3. The third planarization layer 190 may flatten steps due to the third data metal layer DTL3. The third planarization layer 190 may be made of an organic layer such as acryl resin, epoxy resin, phenolic resin, polyamide resin, or polyimide resin.

The fourth data metal layer DTL4 may be disposed on the third planarization layer 190. The fourth data metal layer DTL4 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The fourth data metal layer DTL4 may include anode pad electrodes APD, cathode pad electrodes CPD, and a fourth sub-pad SPD4. Each of the anode pad electrodes APD may be connected to a third connection electrode CE3 through a fourth contact hole CT4 penetrating the third planarization layer 190. The cathode pad electrodes CPD may be supplied with a first power supply voltage which is a low potential voltage. The fourth sub-pad SPD4 may be formed of the same material or a similar material as the anode pad electrodes APD and the cathode pad electrodes CPD in the same process, but embodiments are not limited thereto.

The thin-film transistor layer TFTL may further include a transparent conductive layer TCO, a fifth sub-pad SPD5, and a first passivation layer PVX1.

The transparent conductive layer TCO may be disposed on each of the anode pad electrodes APD and the cathode pad electrodes CPD. The transparent conductive layer TCO may be disposed to increase adhesion to a first contact electrode CTE1 and a second contact electrode CTE2 of each of the light emitting elements LE.

The fifth sub-pad SPD5 may be disposed on the fourth sub-pad SPD4. The fifth sub-pad SPD5 may be formed of the same material or a similar material as the transparent conductive layer TCO in the same process, but embodiments are not limited thereto.

The transparent conductive layer TCO and the fifth sub-pad SPD5 may be made of a transparent conductive oxide such as indium tin oxide (ITO) or indium zinc oxide (IZO).

The first passivation layer PVX1 may be disposed on the anode pad electrodes APD, the cathode pad electrodes CPD, the transparent conductive layer TCO, and a first pad PD1. The first passivation layer PVX1 may be disposed to cover edges of the anode pad electrodes APD, the cathode pad electrodes CPD, the transparent conductive layer TCO, and the first pad PD1. The first passivation layer PVX1 may be made of an inorganic layer, for example, a silicon nitride layer, a silicon oxynitride layer, a silicon oxide layer, a titanium oxide layer, or an aluminum oxide layer.

Each of the light emitting elements LE is illustrated as a flip-chip type micro-LED in which the first contact electrode CTE1 and the second contact electrode CTE2 face the anode pad electrode APD and the cathode pad electrode CPD. Each of the light emitting elements LE may be an inorganic light emitting element made of an inorganic material such as GaN.

Each of the light emitting elements LE may have a length of several to hundreds of μm in the first direction DR1, in the second direction DR2, and in the third direction DR3. For example, each of the light emitting elements LE may have a length of about 100 μm or less in the first direction DR1, in the second direction DR2, and in the third direction DR3.

The light emitting elements LE may be grown on a semiconductor substrate such as a silicon wafer. Each of the light emitting elements LE may be directly transferred from the silicon wafer onto an anode pad electrode APD and a cathode pad electrode CPD of the substrate SUB. For example, each of the light emitting elements LE may be transferred onto an anode pad electrode APD and a cathode pad electrode CPD of the substrate SUB by an electrostatic method using an electrostatic head or a stamping method using an elastic polymer material such as PDMS or silicon as a transfer substrate.

Each of the light emitting elements LE may be a light emitting structure including a base substrate SSUB, an n-type semiconductor NSEM, an active layer MQW, a p-type semiconductor PSEM, the first contact electrode CTE1, and the second contact electrode CTE2.

The base substrate SSUB may be a sapphire substrate, but embodiments are not limited thereto.

The n-type semiconductor NSEM may be disposed on a surface of the base substrate SSUB. For example, the n-type semiconductor NSEM may be disposed on a lower surface of the base substrate SSUB. The n-type semiconductor NSEM may be made of GaN doped with an n conductivity-type dopant such as Si, Ge, or Sn.

The active layer MQW may be disposed on a portion of a surface of the n-type semiconductor NSEM. The active layer MQW may include a material having a single or multiple quantum well structure. In case that the active layer MQW may include a material having a multiple quantum well structure, it may have a structure in which a plurality of well layers and a plurality of barrier layers may be alternately stacked each other. Here, the well layers may be made of InGaN, and the barrier layers may be made of GaN or AlGaN, but embodiments are not limited thereto. For example, the active layer MQW may have a structure in which a semiconductor material having a large band gap energy and a semiconductor material having a small band gap energy may be alternately stacked each other or may include different group 3 to 5 semiconductor materials depending on the wavelength band of light that it emits.

The p-type semiconductor PSEM may be disposed on a surface of the active layer MQW. The p-type semiconductor PSEM may be made of GaN doped with a p conductivity-type dopant such as Mg, Zn, Ca, Se, or Ba.

The first contact electrode CTE1 may be disposed on the p-type semiconductor PSEM, and the second contact electrode CTE2 may be disposed on another portion of the surface of the n-type semiconductor NSEM. The portion of the surface of the n-type semiconductor NSEM on which the second contact electrode CTE2 is disposed may be spaced apart from the portion of the surface of the n-type semiconductor NSEM on which the active layer MQW is disposed.

In an embodiment, the first contact electrode CTE1 and the anode pad electrode APD may be bonded to each other through a conductive adhesive member such as an anisotropic conductive film or an anisotropic conductive paste. In an embodiment, the first contact electrode CTE1 and the anode pad electrode APD may be bonded to each other through a soldering process.

The first pad PD1 may include the first through fifth sub-pads SPD1 through SPD5. The second sub-pad SPD2 may be disposed on the first sub-pad SPD1, and the third sub-pad SPD3 may be disposed on the second sub-pad SPD2. The fourth sub-pad SPD4 may be disposed on the third sub-pad SPD3, and the fifth sub-pad SPD5 may be disposed on the fourth sub-pad SPD4. An upper surface of the first sub-pad SPD1 may contact a lower surface of the second sub-pad SPD2, and an upper surface of the second sub-pad SPD2 may contact a lower surface of the third sub-pad SPD3. An upper surface of the third sub-pad SPD3 may contact a lower surface of the fourth sub-pad SPD4, and an upper surface of the fourth sub-pad SPD4 may contact a lower surface of the fifth sub-pad SPD5.

The first through fifth sub-pads SPD1 through SPD5 may directly contact adjacent sub-pads. The first through fifth sub-pads SPD1 through SPD5 may be electrically connected to each other through the adjacent sub-pads.

A rear connection wiring BCL may be disposed on the rear surface of the substrate SUB. The rear connection wiring BCL may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

A second pad PD2 may be disposed at an end of the rear connection wiring BCL, and a third pad PD3 may be disposed at the other end of the rear connection wiring BCL. The second pad PD2 and the third pad PD3 may be made of a transparent conductive oxide such as indium tin oxide (ITO) or indium zinc oxide (IZO).

A fourth planarization layer 170 may be disposed on the rear connection wiring BCL and the rear surface of the substrate SUB. The fourth planarization layer 170 may flatten steps due to the second pad PD2, the rear connection wiring BCL, and the third pad PD3. The fourth planarization layer 170 may be made of an organic layer such as acryl resin, epoxy resin, phenolic resin, polyamide resin, or polyimide resin.

A second passivation layer PVX2 may be disposed on the fourth planarization layer 170. The second passivation layer PVX2 may be made of an inorganic layer, for example, a silicon nitride layer, a silicon oxynitride layer, a silicon oxide layer, a titanium oxide layer, or an aluminum oxide layer.

A side wiring SIL may be disposed on the first surface FS, the first chamfered surface CS1, the first side surface SS1, the fifth chamfered surface CS5, and the second surface BS of the substrate SUB. The side wiring SIL may be disposed on the first pad PD1 on an edge of the first surface FS of the substrate SUB and may be connected to the first pad PD1. The side wiring SIL may be disposed on the second pad PD2 on an edge of the second surface BS of the substrate SUB and may be connected to the second pad PD2. The side wiring SIL may contact the first chamfered surface CS1, the first side surface SS1, and the fifth chamfered surface CS5 of the substrate SUB.

An overcoat layer OC may be disposed on the first surface FS, the first chamfered surface CS1, the first side surface SS1, the fifth chamfered surface CS5, and the second surface BS of the substrate SUB. The overcoat layer OC may completely cover the side wiring SIL. For example, the overcoat layer OC may completely cover upper and side surfaces of the side wiring SIL.

The overcoat layer OC may overlap the first pad PD1 and the second pad PD2 in the thickness direction, for example, in the third direction DR3. The overcoat layer OC may cover the first pad PD1 and the second pad PD2.

In an embodiment, the overcoat layer OC may cover side surfaces of the first planarization layer 160, the second planarization layer 180, and the third planarization layer 190. The overcoat layer OC may be formed on a step between the first planarization layer 160 and the second planarization layer 180 and/or a step between the second planarization layer 180 and the third planarization layer 190. Accordingly, the overcoat layer OC may have a larger contact area and thus may be more firmly attached to the display panel 100. In an embodiment, as illustrated in the drawings, the overcoat layer OC may cover the side surfaces of the first planarization layer 160 and the second planarization layer 180 and may not cover the side surface of the third planarization layer 190. It is possible to prevent the overcoat layer OC from intruding onto the light emitting elements LE, the anode pad electrodes APD, and the cathode pad electrodes CPD.

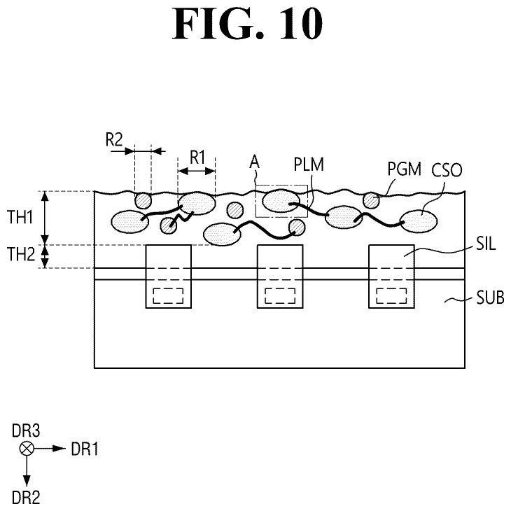

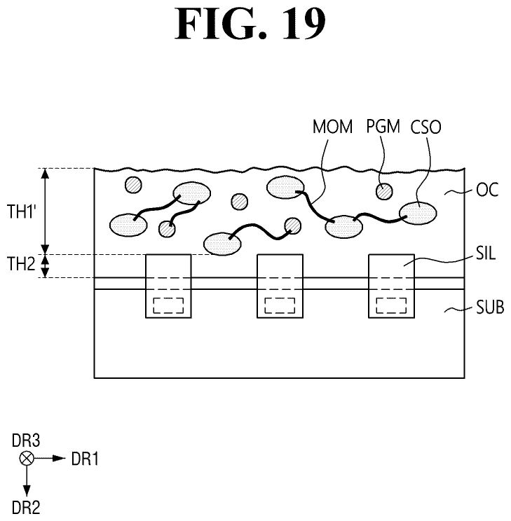

The overcoat layer OC may be made of an organic layer such as acryl resin, epoxy resin, phenolic resin, polyamide resin, or polyimide resin. The above materials of the overcoat layer OC may serve as a binder. For example, in a method of fabricating a display device which will be described later, monomers MOM (see FIG. 19) of the above materials may be changed to polymers PLM (see FIG. 10) by a polymerization reaction. In this process, the monomers MOM may serve to closely attach and agglomerate other particles included in the overcoat layer OC.

The overcoat layer OC may include a light blocking pigment. For example, the overcoat layer OC may include at least any one of a carbon pigment, an RGB mixed pigment, a graphite pigment, and a chromium (Cr) pigment.

The overcoat layer OC may include at least any one of calcium carbonate (CaCO₃) and xCaO·ySiO₂·zH₂O (x, y, and z are natural numbers). For example, the overcoat layer OC may include particles of a cement component such as 3CaO·2SiO₂·3H₂O. The overcoat layer OC may include xCaO·ySiO₂·zH₂O (x, y, and z are natural numbers) formed through a pozzolanic reaction using CaCO₃, SiO₂, and H₂O as reactants in the display device fabrication method which will be described later. A portion of CaCO₃ may remain as it is without participating in the reaction and may be included in the overcoat layer OC.

Since the display device 10 according to the current embodiment may include materials such as calcium carbonate (CaCO₃) and xCaO·ySiO₂·zH₂O (x, y, and z are natural numbers), the damp-proof properties, strength, and bondability of the overcoat layer OC can be improved. Accordingly, expansion and peeling due to high temperature, high humidity, and external friction can be minimized.

A circuit board 200 may be disposed on the rear surface of the substrate SUB. The circuit board 200 may be connected to the third pad PD3, which is exposed without being covered by the fourth planarization layer 170 and the second passivation layer PVX2, using a conductive adhesive member CAM. The circuit board 200 may be connected to the third pad PD3 through the conductive adhesive member CAM. The conductive adhesive member CAM may be an anisotropic conductive film or an anisotropic conductive paste.

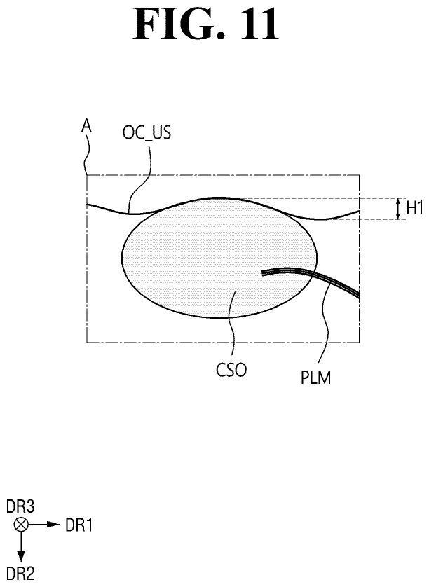

FIG. 10 is a schematic plan view illustrating the substrate SUB, the side wirings SIL, and the overcoat layer OC according to an embodiment. FIG. 11 is an enlarged view of portion ‘A’ in FIG. 10.

Referring to FIGS. 10 and 11, the overcoat layer OC may include first particles CSO including at least one of calcium carbonate (CaCO₃) and xCaO·ySiO₂·zH₂O (x, y, and z are natural numbers) and second particles PGM including a light blocking pigment.

In an embodiment, the size of the first particles CSO may be larger than the size of the second particles PGM. For example, the size of the first particles CSO may be 1 to 3 times the size of the second particles PGM. For example, the size of the first particles CSO may be in a range of about 0.3 to about 2 μm.

According to the display device 10 of the current embodiment, the size of the first particles CSO including at least any one of calcium carbonate (CaCO₃) and xCaO·ySiO₂·zH₂O (x, y, and z are natural numbers) may be larger than the size of the second particles PGM including a light blocking pigment. In the display device fabrication method which will be described later, the size of the first particles CSO is made smaller than three times the size of the second particles PGM through a milling process, so that the overcoat layer OC can have an even particle size. Accordingly, the roughness of a surface OC_US of the overcoat layer OC can be minimized, and peeling due to surface friction can be minimized. Here, the particle size may be an average size of each of the first and second particles CSO and PGM.

For example, as illustrated in the drawings, the surface OC_US of the overcoat layer OC may include uneven patterns having irregular shapes according to the particle size of the overcoat layer OC. Here, a height difference H1 between uppermost and lowermost ends of the uneven patterns may be reduced by reducing the size of the first particles CSO. For example, the height difference H1 between the uppermost and lowermost ends of the uneven patterns may be within about 0.5 μm. Accordingly, the roughness of the surface OC_US of the overcoat layer OC can be minimized, and peeling due to surface friction can be minimized.

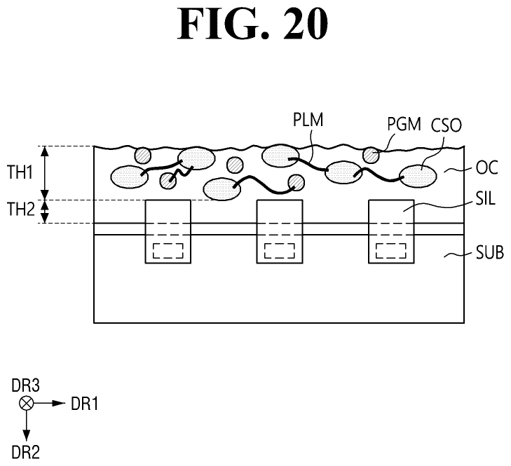

An average thickness TH1 of the overcoat layer OC may be greater than an average thickness TH2 of the side wirings SIL. For example, the average thickness TH1 of the overcoat layer OC may be 1 to 3 times the average thickness TH2 of the side wirings SIL. Here, the thickness may refer to a minimum distance among distances from a point on the lower surface of the overcoat layer OC or each side wiring SIL to the upper surface. The average thickness may refer to an average value of these thicknesses. As polymers PLM such as epoxy resin and/or acrylic resin are formed during a curing process in the display device fabrication method which will be described later, particles in the overcoat layer OC may be densely concentrated. Accordingly, the average thickness TH1 of the overcoat layer OC may be reduced compared with the average thickness before the curing process. This will be described later with reference to FIGS. 19 and 20.

If the average thickness TH1 of the overcoat layer OC is smaller than the average thickness TH2 of the side wirings SIL, the overcoat layer OC cannot perform the function of protecting the side wirings SIL. If the average thickness TH1 of the overcoat layer OC is greater than three times the average thickness TH2 of the side wirings SIL, the overcoat layer OC may exceed the height of the planarization layers 160, 180 and 190 to intrude into the area of the light emitting elements LE and may increase a dead space by increasing a side thickness of the display device 10. Herein, the term “dead space” may be understood as a space which is devoted to accommodating one or more components that, either singularly or plurally, perform an intended function.

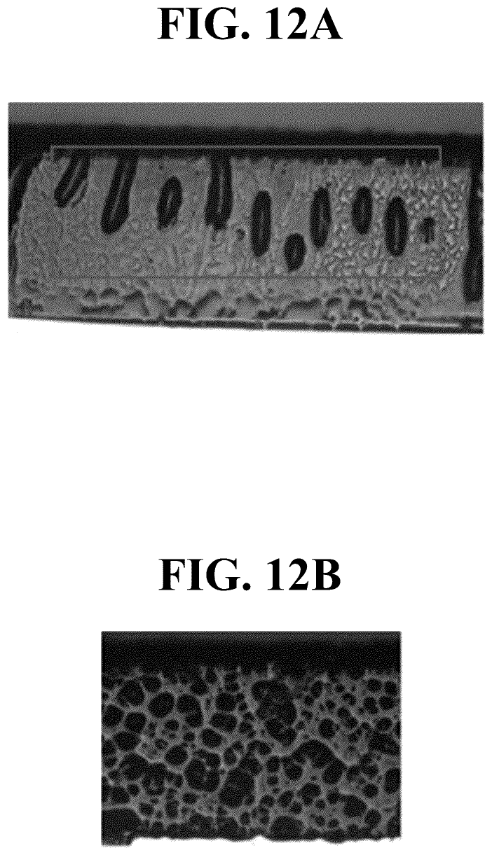

FIGS. 12A and 12B each are a photograph comparing a surface of a conventional overcoat layer and a surface of an overcoat layer according to an embodiment. FIG. 12A shows the surface of the conventional overcoat layer, and FIG. 12B shows the surface of the overcoat layer according to the embodiment.

Referring to FIGS. 12A and 12B, the photograph compares the surfaces of the overcoat layers of a conventional display device and a display device according to an embodiment left for a given period of time under a high temperature and high humidity condition. For example, the photograph shows the result of leaving the overcoat layers for about 168 hours (one week) at a temperature of about 85° C. and a humidity of about 85%.

The conventional overcoat layer shown in FIG. 12A may not include calcium carbonate (CaCO₃), but may include barium sulfate (BaSO₄). The surface hardness of the conventional overcoat layer may be lower than that of the overcoat layer according to the embodiment. Accordingly, a number of scratches and peeling due to expansion may be observed on the surface of the conventional overcoat layer.

On the other hand, it can be seen that scratches and peeling due to expansion are not observed on the surface of the overcoat layer according to the embodiment shown in FIG. 12B. Calcium carbonate (CaCO₃) and xCaO·ySiO₂·zH₂O particles (x, y, and z are natural numbers) may be observed on the surface of the overcoat layer according to the embodiment. These calcium carbonate (CaCO₃) and xCaO·ySiO₂·zH₂O particles (x, y, and z are natural numbers) may act like a kind of cement and show effects of preventing moisture permeation, reinforcing strength, and improving adhesion.

A method of fabricating a display device according to an embodiment will now be described.

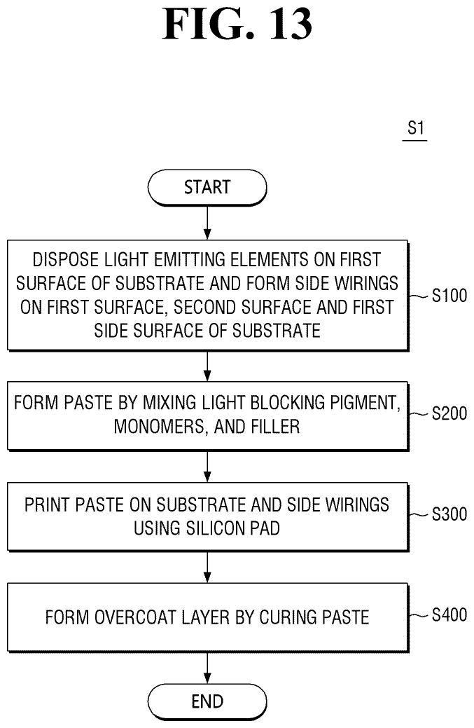

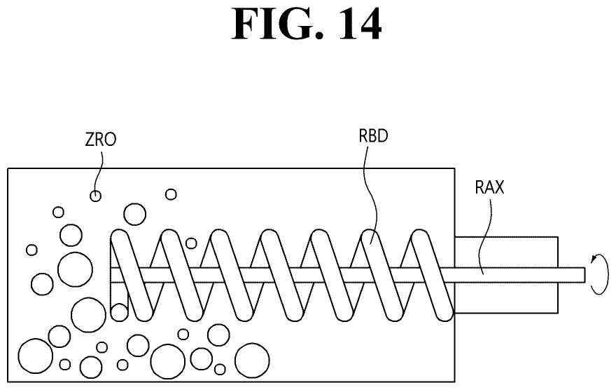

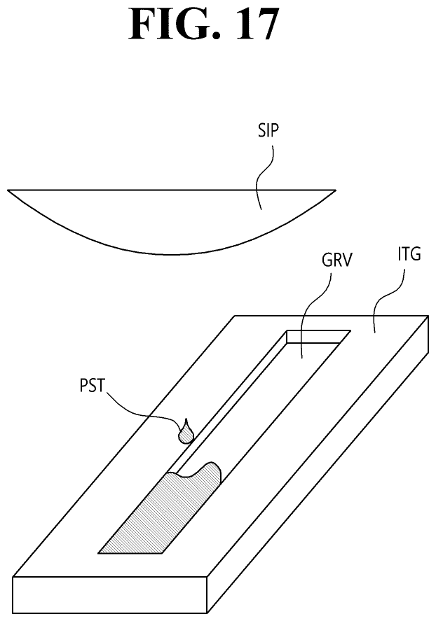

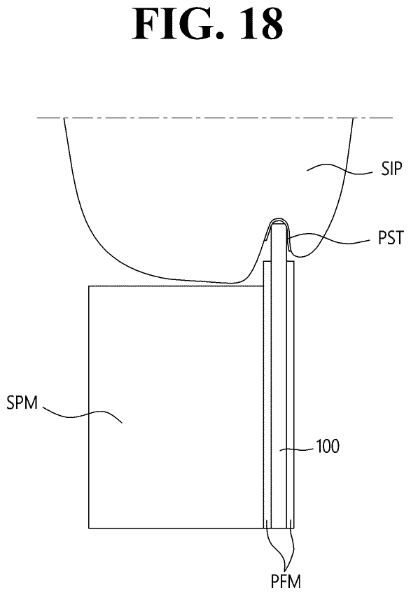

FIG. 13 is a flowchart illustrating a method of fabricating a display device according to an embodiment. FIGS. 14 through 16B are example views for explaining operation S200 of FIG. 13. FIGS. 17 and 18 are example views for explaining operation S300 of FIG. 13. FIGS. 19 and 20 are example views for explaining operation S400 of FIG. 13.

Referring to FIGS. 13 through 20, the method (S1) of fabricating the display device according to the embodiment may include preparing a substrate including a first surface, a second surface opposite the first surface and a first side surface disposed between the first surface and the second surface, disposing light emitting elements on the first surface, and forming side wirings on the first surface, the first side surface and the second surface (operation S100), forming a paste by mixing a light blocking pigment, monomers and a filler (operation S200), printing the paste on the substrate and the side wirings using a silicon pad (operation S300), and forming an overcoat layer by curing the paste (operation S400).

First, a substrate including a first surface, a second surface opposite the first surface, and a first side surface disposed between the first surface and the second surface may be prepared, light emitting elements may be disposed on the first surface, and side wirings may be formed on the first surface, the first side surface and the second surface (operation S100).

Since the substrate SUB, the light emitting elements LE, and the side wirings SIL have been described above with reference to FIG. 8, etc., a description thereof will be omitted.

Second, a light blocking pigment, monomers, and a filler may be mixed to form a paste (operation S200). The paste may be formed by mixing the light blocking pigment, the monomers, and the filler.

As described above, the light blocking pigment is a pigment included in the overcoat layer OC and may include at least any one of a carbon pigment, an RGB mixed pigment, a graphite pigment, and a chromium pigment.

The monomers may include acrylic resin, epoxy resin, phenolic resin, polyamide resin, or polyimide resin as described above. The monomers may serve as a binder in the process of curing the paste during the formation of the overcoat layer OC. For example, the monomers may be changed into polymers by a polymerization reaction. In this process, the monomers may serve to closely attach and agglomerate other particles included in the overcoat layer OC.

The filler may include CaCO₃, SiO₂, and H₂O. In an embodiment, the filler may be included at a range of about 10 to about 20 wt % based on the total mass of the paste. CaCO₃ may be included in the filler at a range of about 95 to about 98 wt % based on the total mass of the filler. SiO₂ may be included in the filler at a range of about 0.5 to about 3 wt % based on the total mass of the filler. H₂O may be included in the filler at a range of about 0.5 to about 1 wt % based on the total mass of the filler.

In an embodiment, CaCO₃ may be included in the filler at a range of about 12 to about 15 wt % based on the total mass of the paste. SiO₂ may be included in the filler at a range of about 2 to about 4 wt % based on the total mass of the paste.

If CaCO₃ is included at less than about 12 wt % based on the total mass of the paste, the strength of the overcoat layer cannot be sufficiently maintained after curing. Therefore, surface scratches, swelling, and peeling cannot be improved. If CaCO₃ is included at greater than about 15 wt % based on the total mass of the paste, the concentration of the paste may increase, resulting in poor printability. Therefore, the paste may not be evenly printed on the display device.

In an embodiment, the paste may further include a curing agent. For example, the curing agent may include dicyandiamide (DCDA). The curing agent may facilitate the polymerization reaction by participating in a curing reaction together with the monomers and may contribute to the formation of polymers. The curing agent additionally included may improve the strength and adhesion of the overcoat layer.

In the forming of the paste (operation S200), a milling process may be performed to ensure that the ingredients of the paste are evenly mixed and to prevent CaCO₃ of the filler from being concentrated and thus increasing the size of particles. For example, a milling process using zirconia balls ZRO may be performed. The zirconia balls ZRO may be zirconia oxide (ZrOm) balls (m is a natural number). In the milling process, as a rotating body RBD rotates along a rotational radius of a rotating shaft RAX, the zirconia balls ZRO may also rotate or move. At this time, particles included in the ingredients of the paste, particularly CaCO₃ particles, may be pulverized.

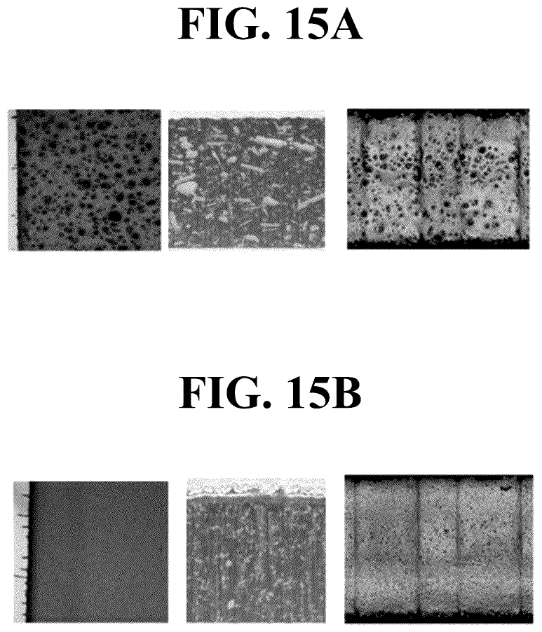

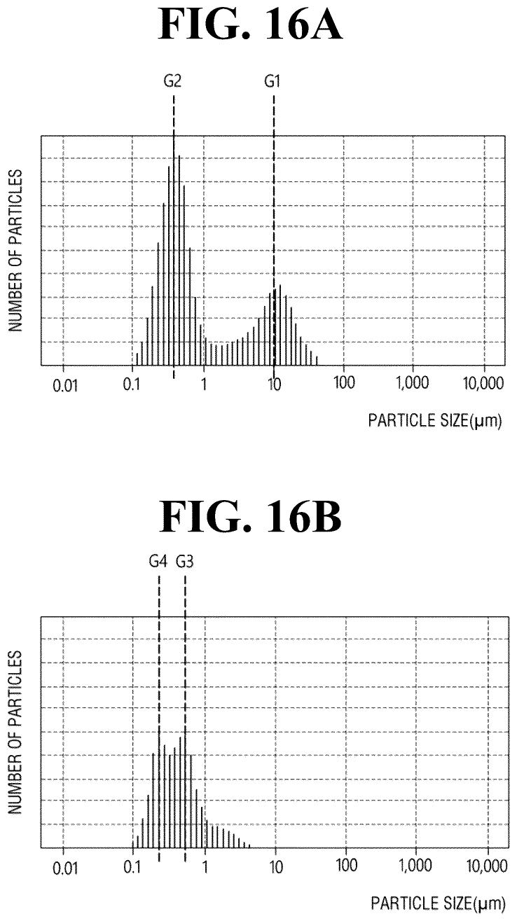

Referring to FIGS. 15A, 15B, 16A, and 16B, FIG. 15A is a photograph showing a surface and cross section of an overcoat layer according to a conventional method of fabricating a display device, and FIG. 15B is a photograph showing a surface and cross section of an overcoat layer according to a method of fabricating a display device according to an embodiment. FIG. 16A is a graph showing the particle size distribution of the overcoat layer according to the conventional method of fabricating the display device, and FIG. 16B is a graph showing the particle size distribution of the overcoat layer according to the method of fabricating the display device according to the embodiment.

As shown in FIGS. 15A and 15B, the particle size of the overcoat layer according to the conventional display device fabrication method in which a milling process using zirconia balls is not performed is larger than the particle size of the overcoat layer according to the fabrication method according to the embodiment in which a milling process using zirconia balls is performed.

As shown in FIGS. 16A and B, an average size G1 of first particles CSO (see FIG. 10) of the overcoat layer according to the conventional method of fabricating the display device may be larger, for example, 10 to 20 times larger than an average size G2 of second particles PGM (see FIG. 10). On the other hand, an average size G3 of first particles CSO (see FIG. 10) of the overcoat layer according to the fabrication method according to the embodiment may be similar or slightly larger than an average size G4 of second particles PGM (see FIG. 10). For example, the average size G3 of the first particles CSO (see FIG. 10) may be 1 to 3 times the average size G4 of the second particles PGM (see FIG. 10).

Therefore, the particle size of the overcoat layer after curing can be minimized, and the particles can be made even. Since the surface roughness of the overcoat layer is minimized, peeling due to surface friction can be minimized.

Third, the paste may be printed on the substrate and the side wirings using a silicon pad (operation S300).

A paste PST formed in operation S200 may be applied to an intaglio plate ITG. The intaglio plate ITG may include a groove GRV, and the paste PST may be applied to the groove GRV. The paste PST may be ejected using an inkjet method or a screen printing method. A length of the groove GRV in a direction in which the groove GRV extends may be equal to or greater than a length of the overcoat layer in a direction in which the overcoat layer extends.

A silicon pad SIP may be coated with the paste PST applied on the intaglio plate ITG, and the paste PST may be printed on the substrate and the side wirings of a display panel 100 by the silicon pad SIP. In an embodiment, a support member SPM may be positioned in one direction or a direction of the display panel 100 to prevent shaking of the display panel 100. In an embodiment, a protective film PFM may be disposed on both surfaces of the display panel 100 to minimize the impact applied to the display panel 100. The silicon pad SIP may be made of a soft material, may have low hardness, and may be recessed along the shape of a side surface of the display device in case that in contact with the side surface of the display device. In this process, the paste PST coated on the silicon pad SIP may be printed on the substrate and the side wirings.

Fourth, the overcoat layer may be formed by curing the paste printed on the display device (operation S400).

The paste may be cured by heat applied from the outside. For example, monomers MOM included in the paste may be changed to polymers PLM by a radical polymerization reaction. Accordingly, the particles (CSO and PGM) included in the paste may adhere and agglomerate with each other. In this process, the average thickness TH1 of the overcoat layer OC may become smaller than an average thickness TH1′ of the overcoat layer OC before curing. The average thickness TH1 of the overcoat layer OC after curing may be 1 to 3 times the average thickness TH2 of the side wirings SIL as described above.

In an embodiment, the paste may be heated in a heating member such as an oven at a range of about 180 to about 220° C. for about 25 to about 35 minutes. In an embodiment, the paste may be heated by irradiating laser light such as infrared light. The laser light may be applied with a power of a range of about 0.9 to about 1.1 W and a repetition rate of a range of about 60 to about 90 kHz, but embodiments are not limited thereto.

In the process of curing the paste, CaCO₃ and SiO₂ included in the paste may cause a pozzolanic reaction together with H₂O to generate xCaO·ySiO₂-zH₂O (x, y, and z are natural numbers). A portion of CaCO₃ included in the paste may remain as it is without participating in the reaction and may be included in the overcoat layer OC.

Since the display device according to the current embodiment may include materials such as calcium carbonate (CaCO₃) and xCaO·ySiO₂·zH₂O (x, y, and z are natural numbers), the damp-proof properties, strength, and bondability of the overcoat layer OC can be improved. Accordingly, expansion and peeling due to high temperature, high humidity, and external friction can be minimized.

A tiled display device including the display device 10 of FIG. 1 in a plural number will now be described.

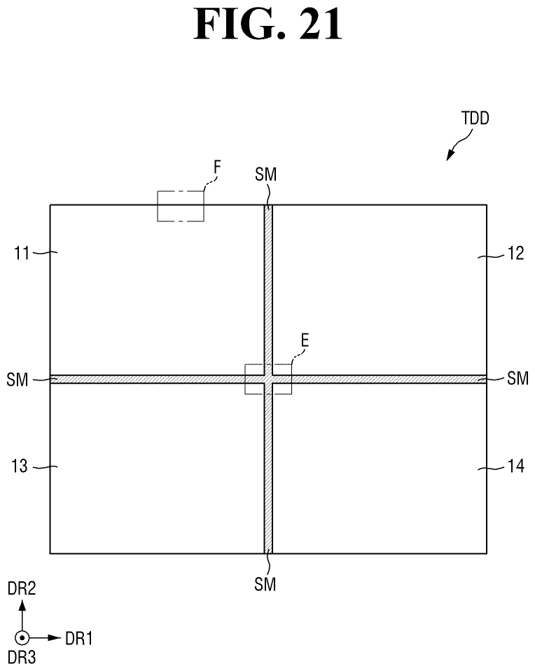

FIG. 21 is a schematic plan view of a tiled display device TDD according to an embodiment.

Referring to FIG. 21, the tiled display device TDD may include a plurality of display devices 11 through 14 and a seam SM. For example, the tiled display device TDD may include a first display device 11, a second display device 12, a third display device 13, and a fourth display device 14.

The display devices 11 through 14 may be arranged in a grid shape. The display devices 11 through 14 may be arranged in a matrix of M (M is a natural number) rows and N (N is a natural number) columns. For example, the first display device 11 and the second display device 12 may neighbor each other in the first direction DR1. The first display device 11 and the third display device 13 may neighbor each other in the second direction DR2. The third display device 13 and the fourth display device 14 may neighbor each other in the first direction DR1. The second display device 12 and the fourth display device 14 may neighbor each other in the second direction DR2.

However, the number and arrangement of the display devices 11 through 14 in the tiled display device TDD are not limited to those illustrated in FIG. 21. The number and arrangement of the display devices 11 through 14 in the tiled display device TDD may be determined by the size of each of the display devices 11 through 14 and the tiled display device TDD and the shape of the tiled display device TDD.

The display devices 11 through 14 may have the same size, but embodiments are not limited thereto. For example, the display devices 11 through 14 may also have different sizes.

Each of the display devices 11 through 14 may be shaped like a rectangle including long sides and short sides. The long sides or short sides of the display devices 11 through 14 may be connected to each other. Some or all of the display devices 11 through 14 may be disposed at an edge of the tiled display device TDD and may form a side of the tiled display device TDD. At least one of the display devices 11 through 14 may be disposed at at least one corner or a corner of the tiled display device TDD and may form two adjacent sides of the tiled display device TDD. At least one of the display devices 11 through 14 may be surrounded by or adjacent to other display devices.

Each of the display devices 11 through 14 may be substantially the same as the display device 10 described above with reference to FIG. 1, etc. Therefore, a description of each of the display devices 11 through 14 will be omitted.

The seam SM may include a coupling member or an adhesive member. The display devices 11 through 14 may be connected to each other through the coupling member or the adhesive member of the seam SM. The seam SM may be disposed between the first display device 11 and the second display device 12, between the first display device 11 and the third display device 13, between the second display device 12 and the fourth display device 14, and between the third display device 13 and the fourth display device 14.

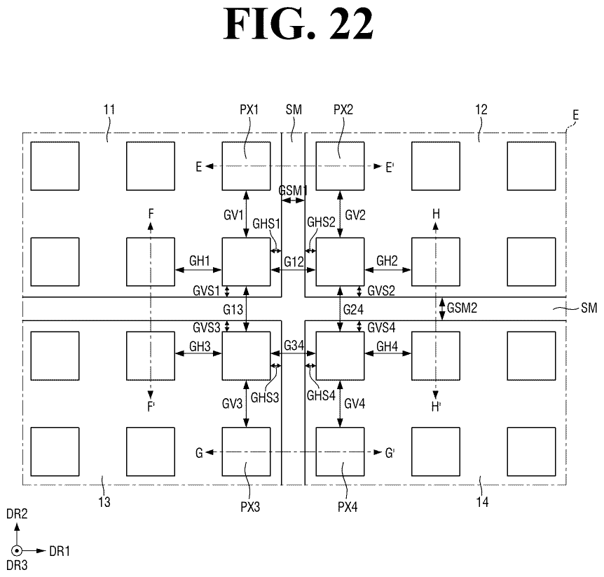

FIG. 22 is an enlarged schematic plan view illustrating area E of FIG. 21 in detail.

Referring to FIG. 22, the seam SM may have a planar shape of a cross or a plus sign in a central area of the tiled display device TDD in which the first display device 11, the second display device 12, the third display device 13, and the fourth display device 14 are adjacent to each other. The seam SM may be disposed between the first display device 11 and the second display device 12, between the first display device 11 and the third display device 13, between the second display device 12 and the fourth display device 12, and between the third display device 13 and the fourth display device 14.

The first display device 11 may include first pixels PX1 arranged in a matrix in the first direction DR1 and the second direction DR2 to display an image. The second display device 12 may include second pixels PX2 arranged in a matrix in the first direction DR1 and the second direction DR2 to display an image. The third display device 13 may include third pixels PX3 arranged in a matrix in the first direction DR1 and the second direction DR2 to display an image. The fourth display device 14 may include fourth pixels PX4 arranged in a matrix in the first direction DR1 and the second direction DR2 to display an image.

A minimum distance between the first pixels PX1 neighboring in the first direction DR1 may be defined as a first horizontal separation distance GH1, and a minimum distance between the second pixels PX2 neighboring in the first direction DR1 may be defined as a second horizontal separation distance GH2. The first horizontal separation distance GH1 and the second horizontal separation distance GH2 may be substantially the same.

The seam SM may be disposed between the first pixels PX1 and the second pixels PX2 neighboring in the first direction DR1. A minimum distance G12 between the first pixels PX1 and the second pixels PX2 neighboring in the first direction DR1 may be the sum of a minimum distance GHS1 between the first pixels PX1 and the seam SM in the first direction DR1, a minimum distance GHS2 between the second pixels PX2 and the seam SM in the first direction DR1, and a width GSM1 of the seam SM in the first direction DR1.

The minimum distance G12 between the first pixels PX1 and the second pixels PX2 neighboring in the first direction DR1, the first horizontal separation distance GH1, and the second horizontal separation distance GH2 may be substantially the same. To this end, the minimum distance GHS1 between the first pixels PX1 and the seam SM in the first direction DR1 may be smaller than the first horizontal separation distance GH1, and the minimum distance GHS2 between the second pixels PX2 and the seam SM in the first direction DR1 may be smaller than the second horizontal separation distance GH2. The width GSM1 of the seam SM in the first direction DR1 may be smaller than the first horizontal separation distance GH1 or the second horizontal separation distance GH2.

A minimum distance between the third pixels PX3 neighboring in the first direction DR1 may be defined as a third horizontal separation distance GH3, and a minimum distance between the fourth pixels PX4 neighboring in the first direction DR1 may be defined as a fourth horizontal separation distance GH4. The third horizontal separation distance GH3 and the fourth horizontal separation distance GH4 may be substantially the same.

The seam SM may be disposed between the third pixels PX3 and the fourth pixels PX4 neighboring in the first direction DR1. A minimum distance G34 between the third pixels PX3 and the fourth pixels PX4 neighboring in the first direction DR1 may be the sum of a minimum distance GHS3 between the third pixels PX3 and the seam SM in the first direction DR1, a minimum distance GHS4 between the fourth pixels PX4 and the seam SM in the first direction DR1, and the width GSM1 of the seam SM in the first direction DR1.

The minimum distance G34 between the third pixels PX3 and the fourth pixels PX4 neighboring in the first direction DR1, the third horizontal separation distance GH3, and the fourth horizontal separation distance GH4 may be substantially the same. To this end, the minimum distance GHS3 between the third pixels PX3 and the seam SM in the first direction DR1 may be smaller than the third horizontal separation distance GH3, and the minimum distance GHS4 between the fourth pixels PX4 and the seam SM in the first direction DR1 may be smaller than the fourth horizontal separation distance GH4. The width GSM1 of the seam SM in the first direction DR1 may be smaller than the third horizontal separation distance GH3 or the fourth horizontal separation distance GH4.

A minimum distance between the first pixels PX1 neighboring in the second direction DR2 may be defined as a first vertical separation distance GV1, and a minimum distance between the third pixels PX3 neighboring in the second direction DR2 may be defined as a third vertical separation distance GV3. The first vertical separation distance GV1 and the third vertical separation distance GV3 may be substantially the same.

The seam SM may be disposed between the first pixels PX1 and the third pixels PX3 neighboring in the second direction DR2. A minimum distance G13 between the first pixels PX1 and the third pixels PX3 neighboring in the second direction DR2 may be the sum of a minimum distance GVS1 between the first pixels PX1 and the seam SM in the second direction DR2, a minimum distance GVS3 between the third pixels PX3 and the seam SM in the second direction DR2, and a width GSM2 of the seam SM in the second direction DR2.

The minimum distance G13 between the first pixels PX1 and the third pixels PX3 neighboring in the second direction DR2, the first vertical separation distance GV1, and the third vertical separation distance GV3 may be substantially the same. To this end, the minimum distance GVS1 between the first pixels PX1 and the seam SM in the second direction DR2 may be smaller than the first vertical separation distance GV1, and the minimum distance GVS3 between the third pixels PX3 and the seam SM in the second direction DR2 may be smaller than the third vertical separation distance GV3. The width GSM2 of the seam SM in the second direction DR2 may be smaller than the first vertical separation distance GV1 or the third vertical separation distance GV3.

A minimum distance between the second pixels PX2 neighboring in the second direction DR2 may be defined as a second vertical separation distance GV2, and a minimum distance between the fourth pixels PX4 neighboring in the second direction DR2 may be defined as a fourth vertical separation distance GV4. The second vertical separation distance GV2 and the fourth vertical separation distance GV4 may be substantially the same.

The seam SM may be disposed between the second pixels PX2 and the fourth pixels PX4 neighboring in the second direction DR2. A minimum distance G24 between the second pixels PX2 and the fourth pixels PX4 neighboring in the second direction DR2 may be the sum of a minimum distance GVS2 between the second pixels PX2 and the seam SM in the second direction DR2, a minimum distance GVS4 between the fourth pixels PX4 and the seam SM in the second direction DR2, and the width GSM2 of the seam SM in the second direction DR2.

The minimum distance G24 between the second pixels PX2 and the fourth pixels PX4 neighboring in the second direction DR2, the second vertical separation distance GV2, and the fourth vertical separation distance GV4 may be substantially the same. To this end, the minimum distance GVS2 between the second pixels PX2 and the seam SM in the second direction DR2 may be smaller than the second vertical separation distance GV2, and the minimum distance GVS4 between the fourth pixels PX4 and the seam SM in the second direction DR2 may be smaller than the fourth vertical separation distance GV4. The width GSM2 of the seam SM in the second direction DR2 may be smaller than the second vertical separation distance GV2 or the fourth vertical separation distance GV4.

As illustrated in FIG. 22, in order to prevent the seam SM from being recognized between images displayed by the display devices 11 through 14, the minimum distance between pixels of neighboring display devices may be substantially the same as the minimum distance between pixels of each of the display devices.

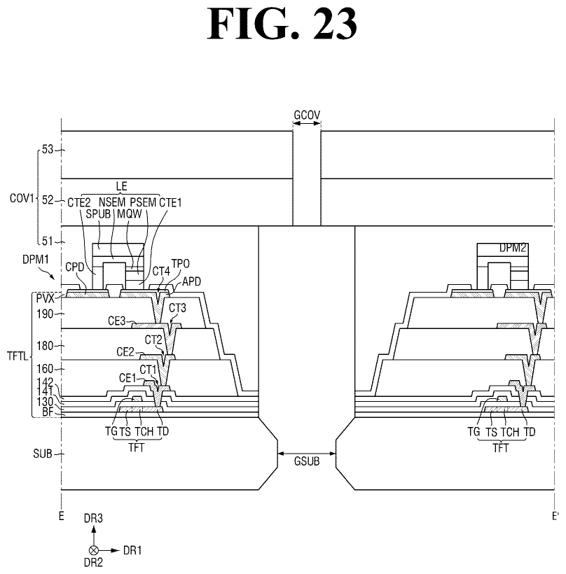

FIG. 23 is a schematic cross-sectional view of an example of the tiled display device TDD taken along line E-E′ of FIG. 22.

Referring to FIG. 23, the first display device 11 may include a first display module DPM1 and a first front cover COV1. The second display device 12 may include a second display module DPM2 and a second front cover COV2.

Each of the first display module DPM1 and the second display module DPM2 may include a substrate SUB, a thin-film transistor layer TFTL, and light emitting elements EL. The thin-film transistor layer TFTL and the light emitting elements EL have already been described in detail with reference to FIGS. 8 and 9. In FIG. 23, descriptions overlapping those of the embodiment of FIGS. 8 and 9 will be omitted.

The substrate SUB may include a first surface on which the thin-film transistor layer TFTL is disposed, a second surface facing the first surface, and a first side surface disposed between the first surface and the second surface. The first surface may be a front surface or an upper surface of the substrate SUB, and the second surface may be a rear surface or a lower surface of the substrate SUB. The substrate SUB may further include a first chamfered surface disposed between the first surface and the first side surface and a second chamfered surface disposed between the second surface and the first side surface.

The first front cover COV1 may be disposed on the substrate SUB. For example, the first front cover COV1 may protrude further than the substrate SUB in the first direction DR1 and the second direction DR2. Therefore, a distance GSUB between the substrate SUB of the first display device 11 and the substrate SUB of the second display device 12 may be greater than a distance GCOV between the first front cover COV1 and the second front cover COV2.

Each of the first front cover COV1 and the second front cover COV2 may include an adhesive member 51, a light transmittance control layer 52 disposed on the adhesive member 51, and an anti-glare layer 53 disposed on the light transmittance control layer 52.

The adhesive member 51 of the first front cover COV1 may attach a light emitting element layer EML of the first display module DPM1 to the first front cover COV1. The adhesive member 51 of the second front cover COV2 may attach a light emitting element layer EML2 of the second display module DPM2 to the second front cover COV2. The adhesive member 51 may be a transparent adhesive member capable of transmitting light. For example, the adhesive member 51 may be an optically clear adhesive film or an optically clear resin.

The anti-glare layer 53 may be designed to diffusely reflect external light to prevent deterioration of image visibility due to the external light being reflected as it is. Accordingly, a contrast ratio of images displayed by the first display device 11 and the second display device 12 may be increased due to the anti-glare layer 53.

The light transmittance control layer 52 may be designed to reduce transmittance of external light or light reflected from the first display module DPM1 and the second display module DPM2. Accordingly, the distance GSUB between the substrate SUB of the first display module DPM1 and the substrate SUB of the second display module DPM2 may be prevented from being recognized from the outside.

The anti-glare layer 53 may be implemented as a polarizing plate, and the light transmittance control layer 52 may be implemented as a phase delay layer, but embodiments are not limited thereto.

The second front cover COV2 may have substantially the same configuration as the first front cover COV1, and thus a detailed description thereof will be omitted.

An example of the tiled display device TDD cut along lines F-F′, G-G′, and H-H′ of FIG. 22 is substantially the same as the example of the tiled display device TDD cut along line E-E′ described above with reference to FIG. 23, and thus a description thereof will be omitted.

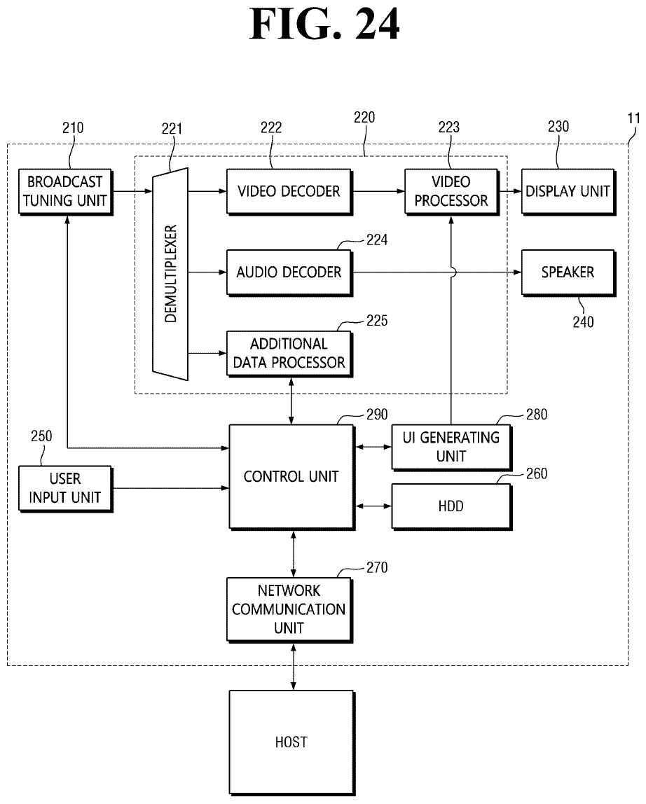

FIG. 24 is a block diagram of the tiled display device TDD according to the embodiment.

In FIG. 24, the first display device 11 and a host system HOST are illustrated for ease of description.

Referring to FIG. 24, the tiled display device TDD according to the embodiment may include the host system HOST, a broadcast tuning unit 210, a signal processing unit 220, a display unit 230, a speaker 240, a user input unit 250, a hard disk drive (HDD) 260, a network communication unit 270, a user interface (UI) generating unit 280, and a control unit 290.

The host system HOST may be implemented as any one of a television system, a home theater system, a set-top box, a navigation system, a DVD player, a Blu-ray player, a PC, a mobile phone system, and a tablet.

A user's command may be input to the host system HOST in various forms. For example, the user's command may be input to the host system HOST through a touch input. For example, the user's command may be input to the host system HOST through a keyboard input or a button input of a remote controller.

The host system HOST may receive original video data corresponding to an original image from the outside. The host system HOST may divide the original video data by the number of display devices. For example, for the first display device 11, the second display device 12, the third display device 13, and the fourth display device 14, the host system HOST may divide the original video data into first video data corresponding to a first image, second video data corresponding to a second image, third video data corresponding to a third image, and fourth video data corresponding to a fourth image. The host system HOST may transmit the first video data to the first display device 11, transmit the second video data to the second display device 12, transmit the third video data to the third display device 13, and transmit the fourth video data to the fourth display device 14.

The first display device 11 may display the first image according to the first video data, the second display device 12 may display the second image according to the second video data, the third display device 13 may display the third image according to the third video data, and the fourth display device 14 may display the fourth image according to the fourth video data. Accordingly, a user may view the original image into which the first through fourth images displayed on the first through fourth display devices 11 through 14 are combined.

The first display device 11 may include the broadcast tuning unit 210, the signal processing unit 220, the display unit 230, the speaker 240, the user input unit 250, the HDD 260, the network communication unit 270, the UI generating unit 280, and the control unit 290.

The broadcast tuning unit 210 may tune a selectable channel frequency under the control of the control unit 290 and receive a broadcast signal of a corresponding channel through an antenna. The broadcast tuning unit 210 may include a channel detection module and a radio frequency (RF) demodulation module.

The broadcast signal demodulated by the broadcast tuning unit 210 is processed by the signal processing unit 220 and then output to the display unit 230 and the speaker 240. Here, the signal processing unit 220 may include a demultiplexer 221, a video decoder 222, a video processor 223, an audio decoder 224, and an additional data processor 225.

The demultiplexer 221 separates the demodulated broadcast signal into a video signal, an audio signal, and additional data. The video signal, the audio signal, and the additional data are restored by the video decoder 222, the audio decoder 224, and the additional data processor 225, respectively. Here, the video decoder 222, the audio decoder 224, and the additional data processor 225 restore the video signal, the audio signal, and the additional data in a decoding format corresponding to an encoding format used in case that the broadcast signal is transmitted.

The decoded video signal is converted by the video processor 223 to fit the vertical frequency, resolution, aspect ratio, etc. that meet the output standard of the display unit 230, and the decoded audio signal is output to the speaker 240.

The display unit 230 may include a display panel 100 on which an image is displayed and a panel driver controlling driving of the display panel 100.

The user input unit 250 may receive a signal transmitted by the host system HOST. The user input unit 250 may be provided to allow a user to select and input commands regarding communication with other display devices as well as data regarding channel selection and UI menu selection and manipulation transmitted by the host system HOST.

The HDD 260 stores various software programs including OS programs, recorded broadcast programs, moving images, photographs, and other data. The HDD 260 may be formed of a storage medium such as a hard disk or a non-volatile memory.

The network communication unit 270 is for short-distance communication with the host system HOST and other display devices. The network communication unit 270 can be implemented as a communication module including an antenna pattern that can implement mobile communication, data communication, Bluetooth, RF, Ethernet, etc.

The network communication unit 270 may transmit and receive wireless signals to and from at least one of a base station, an external terminal, and a server on a mobile communication network constructed according to technical standards or communication methods for mobile communication (for example, Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), 5G, etc.) through an antenna pattern to be described later.

The network communication unit 270 may also transmit and receive wireless signals in a communication network according to wireless Internet technologies through the antenna pattern to be described later. The wireless Internet technologies include, for example, Wireless LAN (WLAN), Wireless-Fidelity (Wi-Fi), Wi-Fi Direct, Digital Living Network Alliance (DLNA), Wireless Broadband (WiBro), World Interoperability for Microwave Access (WiMAX), HSDPA, HSUPA, LTE, and LTE-A. The antenna pattern transmits and receives data according to at least one wireless Internet technology within a range including even Internet technologies not listed above.

The UI generating unit 280 generates a UI menu for communication with the host system HOST and other display devices and can be implemented by an algorithm code and an on-screen display integrated circuit (OSD IC). The UI menu for communication with the host system HOST and other display devices may be a menu for designating a desired digital television for communication and selecting a desired function.

The control unit 290 is responsible for overall control of the first display device 11 and responsible for communication control of the host system HOST and the second through fourth display devices 12 through 14. The control unit 290 can be implemented by a micro controller unit (MCU) which stores a corresponding algorithm code for control and executes the stored algorithm code.

The control unit 290 controls a control command and data corresponding to the input and selection of the user input unit 250 to be transmitted to the host system HOST and the second through fourth display devices 12 through 14 through the network communication unit 270. In case that a selectable control command and data are received from the host system HOST and the second through fourth display devices 12 through 14, the control unit 290 performs an operation according to the control command.

In concluding the detailed description, those skilled in the art will appreciate that many variations and modifications can be made to the disclosed embodiments without substantially departing from the principles of the disclosure. Therefore, the disclosed embodiments are used in a generic and descriptive sense only and not for purposes of limitation.

What is claimed is:

1. A display device comprising:
a substrate comprising:
a first surface;
a second surface opposite the first surface; and
a first side surface disposed between the first surface and the second surface;
a light emitting element disposed on the first surface;
a side wiring disposed on the first surface, the first side surface, and the second surface; and
an overcoat layer covering the side wiring,
wherein the overcoat layer comprises at least one of CaCO₃ and xCaO·ySiO₂·zH₂O where x, y, and z are natural numbers.

2. The display device of claim 1, wherein xCaO·ySiO₂·zH₂O of the overcoat layer is 3CaO·2SiO₂·3H₂O.

3. The display device of claim 1, wherein
the overcoat layer comprises first particles comprising at least one of CaCO₃ and xCaO·ySiO₂·zH₂O and second particles comprising a light blocking pigment, and
a size of the first particles is larger than a size of the second particles.

4. The display device of claim 3, wherein the size of the first particles is about 1 to about 3 times the size of the second particles.

5. The display device of claim 3, wherein
a surface of the overcoat layer comprises substantially uneven patterns having irregular shapes, and
a height difference between uppermost and lowermost ends of the substantially uneven patterns is within about 0.5 μm.

6. The display device of claim 1, wherein xCaO·ySiO₂·zH₂O is generated through a pozzolanic reaction using CaCO₃, SiO₂, and H₂O as reactants.

7. The display device of claim 1, wherein an average thickness of the overcoat layer is about 1 to about 3 times an average thickness of the side wiring.

8. The display device of claim 1, wherein the overcoat layer comprises at least one polymer selected from epoxy resin and acrylic resin.

9. The display device of claim 1, wherein
the substrate comprises a first chamfered surface disposed between the first surface and the first side surface and a second chamfered surface disposed between the second surface and the first side surface,
the side wiring is further disposed on the first chamfered surface and the second chamfered surface, and
the overcoat layer covers all of the first surface, the first chamfered surface, the first side surface, the second chamfered surface, and the second surface.

10. A method of fabricating a display device, the method comprising:
preparing a substrate comprising a first surface, a second surface opposite the first surface, and a first side surface disposed between the first surface and the second surface;
disposing light emitting elements on the first surface;
forming a side wiring on the first surface, the first side surface, and the second surface;
printing a paste on the substrate and the side wiring by a silicon pad; and
forming an overcoat layer by curing the paste,
wherein in the forming of the overcoat layer, CaCO₃ and SiO₂ included in the paste cause a pozzolanic reaction together with H₂O to generate xCaO·ySiO₂·zH₂O where x, y, and z are natural numbers.

11. The method of claim 10, wherein
the paste comprises a light blocking pigment, monomers, and a filler, and
the filler is included at a range of about 10 to about 20 wt % based on the total mass of the paste.

12. The method of claim 11, wherein
CaCO₃ is included at a range of about 12 to about 15 wt % based on the total mass of the paste, and
SiO₂ is included at a range of about 2 to about 4 wt % based on the total mass of the paste.

13. The method of claim 11, wherein the monomers comprise acrylic resin and/or epoxy resin.

14. The method of claim 11, wherein the forming of the paste further comprises pulverizing particles of the filler through milling by zirconia balls.

15. The method of claim 14, wherein
the overcoat layer comprises first particles comprising at least one of CaCO₃ and xCaO·ySiO₂·zH₂O and second particles comprising a light blocking pigment, and
a size of the first particles is larger than a size of the second particles.

16. The method of claim 15, wherein the size of the first particles is about 1 to about 3 times the size of the second particles.

17. The method of claim 10, wherein the forming of the overcoat layer comprises applying heat to the paste at a temperature in a range of about 180 to about 220° C. for about 25 to about 35 minutes.

18. The method of claim 10, wherein the forming of the overcoat layer comprises thermally curing the paste by irradiating infrared light to the paste.

19. The method of claim 10, wherein
the printing of the paste further comprises applying the paste to an intaglio plate, and
in the printing of the paste, the silicon pad is coated with the paste applied on the intaglio plate and prints the paste on the substrate and the side wiring.

20. A tiled display device comprising:
a first display device and a second display device; and
a seam disposed between the first display device and the second display device and connects the first display device to the second display device, wherein
each of the first display device and the second display device comprises:
a substrate comprising:
a first surface;
a second surface opposite the first surface; and
a first side surface disposed between the first surface and the second surface;
a light emitting element disposed on the first surface;
a side wiring disposed on the first surface, the first side surface, and the second surface; and
an overcoat layer covering the side wiring,
wherein the overcoat layer comprises at least one of CaCO₃ and xCaO·ySiO₂·zH₂O where x, y, and z are natural numbers.
